(19) United States
(12) Patent Application Publication
(10) Pub. No.: US 2024/0231231 A1
(43) Pub. Date: Jul. 11, 2024

(54) METHOD FOR FORMING RESIST UNDERLAYER FILM, METHOD FOR PRODUCING SEMICONDUCTOR SUBSTRATE, COMPOSITION, AND RESIST UNDERLAYER FILM

(71) Applicant: JSR CORPORATION, Tokyo (JP)

(72) Inventors: Daiki TATSUBO, Tokyo (JP); Tomoharu KAWAZU, Tokyo (JP); Hiroyuki MIYAUCHI, Tokyo (JP); Yuya HAYASHI, Tokyo (JP); Takashi KATAGIRI, Tokyo (JP); Ryotaro TANAKA, Tokyo (JP)

(73) Assignee: JSR CORPORATION, Tokyo (JP)

(21) Appl. No.: 18/440,124

(22) Filed: Feb. 13, 2024

Related U.S. Application Data
(63) Continuation-in-part of application No. PCT/JP2022/029433, filed on Aug. 1, 2022.

(30) Foreign Application Priority Data
Aug. 18, 2021 (JP) 2021-133576

(51) Int. Cl. G03F 7/11; C09D 161/06; C09D 161/12; H01L 21/308; H01L 21/311

(52) U.S. Cl. CPC G03F 7/11; C09D 161/06; C09D 161/12; H01L 21/3081; H01L 21/31116

(57) ABSTRACT

A method for forming a resist underlayer film includes applying a composition for forming a resist underlayer film directly or indirectly to a substrate to form a coating film. The coating film is heated at a heating temperature of higher than 450° C. and 600° C. or lower in an atmosphere having an oxygen concentration of less than 0.01% by volume. The composition for forming a resist underlayer film includes: a compound including an aromatic ring; a polymer which thermally decomposes at the heating temperature in heating the coating film, and which is other than the compound; and a solvent. The compound has a molecular weight of 400 or more. A content of the polymer is less than a content of the compound in the composition for forming a resist underlayer film.

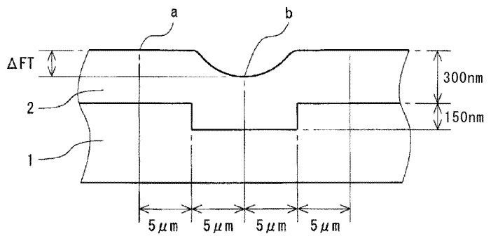

### CROSS-REFERENCE TO RELATED APPLICATIONS

The present application is a continuation-in-part application of International Patent Application No. PCT/JP2022/029433 filed Aug. 1, 2022, which claims priority to Japanese Patent Application No. 2021-133576 filed Aug. 18, 2021. The contents of these applications are incorporated herein by reference in their entirety.

### BACKGROUND OF THE DISCLOSURE

### Technical Field

The present disclosure relates to a method for forming a resist underlayer film, a method for manufacturing a semiconductor substrate, a composition, and a resist underlayer film.

### Background Art

In the manufacture of semiconductor devices, a multilayer resist process is used to obtain a high degree of integration. In this process, a composition for forming a resist underlayer film is first applied onto a substrate to form a resist underlayer film, and a resist composition is applied onto the resist underlayer film to form a resist film. Then, the resist film is exposed through a mask pattern or the like and developed with an appropriate developer to form a resist pattern. Then, the resist underlayer film is subjected to dry etching using this resist pattern as a mask, and further the substrate is subjected to dry etching using the obtained resist underlayer film pattern as a mask, so that a desired pattern can be formed on the semiconductor substrate.

Commonly, a material having a high carbon content is used for resist underlayer films. When such a material having a high carbon content is used for a resist underlayer film, etching resistance during substrate processing is improved, and as a result, more accurate pattern transfer can be performed. As such a resist underlayer film, a thermally curable phenol novolak resin is well known (see JP-A-2000-143937). In addition, it is known that a resist underlayer film formed of a composition for forming a resist underlayer film containing an acenaphthylene-based polymer exhibits favorable characteristics (see JP-A-2001-40293).

### SUMMARY

According to an aspect of the present disclosure, a method for forming a resist underlayer film includes applying a composition for forming a resist underlayer film directly or indirectly to a substrate to form a coating film. The coating film is heated at a heating temperature of higher than 450° C. and 600° C. or lower in an atmosphere having an oxygen concentration of less than 0.01% by volume. The composition for forming a resist underlayer film includes: a compound including an aromatic ring; a polymer which thermally decomposes at the heating temperature in heating the coating film, and which is other than the compound; and a solvent. The compound has a molecular weight of 400 or more. A content of the polymer is less than a content of the compound in the composition for forming a resist underlayer film.

According to another aspect of the present disclosure, a method for manufacturing a semiconductor substrate, including: applying a composition for forming a resist underlayer film directly or indirectly to a substrate to form a coating film. The coating film is heated at a heating temperature of higher than 450° C. and 600° C. or lower in an atmosphere having an oxygen concentration of less than 0.01% by volume to form a resist underlayer film. A resist pattern is formed directly or indirectly on the resist underlayer film. Etching is performed using the resist pattern as a mask. The composition for forming a resist underlayer film includes: a compound including an aromatic ring; a polymer which thermally decomposes at the heating temperature in heating the coating film, and which is other than the compound; and a solvent. The compound has a molecular weight of 400 or more. A content of the polymer is less than a content of the compound in the composition for forming a resist underlayer film.

According to a further aspect of the present disclosure, a composition includes: a compound including an aromatic ring; a polymer which thermally decomposes at a heating temperature of higher than 450° C. and 600° ° C. or lower, and which is other than the compound; and a solvent. The compound has a molecular weight of 400 or more. A content of the polymer is less than a content of the compound in the composition.

According to a further aspect of the present disclosure, a resist underlayer film is formed of the above-described composition.

### BRIEF DESCRIPTION OF THE DRAWINGS

The FIGURE is a schematic plan view for explaining a method for evaluating flatness.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Along with advance in further microfabrication of patterns, resist underlayer films are required to have improved heat resistance and flatness.

One embodiment of the present disclosure relates to a method for forming a resist underlayer film, including:
applying a composition for forming a resist underlayer film directly or indirectly to a substrate (hereinafter also referred to as “applying step”); and
heating a coating film obtained by the applying step at a heating temperature of higher than 450° C. and 600° C. or lower in an atmosphere having an oxygen concentration of less than 0.01% by volume (hereinafter also referred to as “heating step”),
wherein
the composition for forming a resist underlayer film includes:
a compound having an aromatic ring (hereinafter also referred to as “compound [A]”);
a polymer that thermally decomposes at least at the heating temperature in the heating step (excluding the compound having an aromatic ring) (hereinafter also referred to as “polymer [B]”); and
a solvent (hereinafter also referred to as “solvent [C]”),
the compound having an aromatic ring has a molecular weight of 400 or more, and
a content of the polymer in the composition for forming a resist underlayer film is less than a content of the compound having an aromatic ring.

One embodiment of the present disclosure relates to a method for manufacturing a semiconductor substrate, including:
applying a composition for forming a resist underlayer film directly or indirectly to a substrate;
heating a coating film obtained by the applying step at a heating temperature of higher than 450° C. and 600° C. or lower in an atmosphere having an oxygen concentration of less than 0.01% by volume;
forming a resist pattern directly or indirectly on the resist underlayer film formed by the heating step; and
performing etching using the resist pattern as a mask,
wherein
the composition for forming a resist underlayer film includes:
a compound having an aromatic ring;
a polymer that thermally decomposes at least at the heating temperature in the heating step (excluding the compound having an aromatic ring); and
a solvent,
the compound having an aromatic ring has a molecular weight of 400 or more, and
a content of the polymer in the composition for forming a resist underlayer film is less than a content of the compound having an aromatic ring.

One embodiment of the present disclosure relates to a composition for forming a resist underlayer film to be used for a method for forming a resist underlayer film, the method including:
applying a composition for forming a resist underlayer film directly or indirectly to a substrate; and
heating a coating film obtained by the applying step at a heating temperature of higher than 450° C. and 600° C. or lower in an atmosphere having an oxygen concentration of less than 0.01% by volume,
wherein
the composition for forming a resist underlayer film includes:
a compound having an aromatic ring;
a polymer that thermally decomposes at least at the heating temperature in the heating step (excluding the compound having an aromatic ring); and
a solvent,
the compound having an aromatic ring has a molecular weight of 400 or more, and
a content of the polymer is less than a content of the compound having an aromatic ring.

One embodiment of the present disclosure relates to a resist underlayer film formed of the composition for forming a resist underlayer film.

The method for forming a resist underlayer film makes it possible to form a resist underlayer film excellent in heat resistance and flatness. By use of the method for manufacturing a semiconductor substrate, a resist underlayer film excellent in heat resistance and flatness is formed, and therefore, a favorable semiconductor substrate can be obtained. The composition for forming a resist underlayer film can form a resist underlayer film excellent in heat resistance and flatness. The resist underlayer film formed of the composition for forming a resist underlayer film is excellent in heat resistance and flatness. Therefore, these can suitably be used for, for example, manufacturing semiconductor devices expected to be further microfabricated in the future.

### <Method for Forming Resist Underlayer Film>

The method for forming a resist underlayer film includes an applying step and a heating step. The method for forming a resist underlayer film makes it possible to form a resist underlayer film excellent in heat resistance and flatness. Each of the steps will be described below.

### [Applying Step]

In this step, a composition for forming a resist underlayer film formation is applied directly or indirectly to a substrate. In this step, a coating film of the composition for forming a resist underlayer film is formed directly or indirectly on the substrate. The composition for forming a resist underlayer film will be described later.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The method of the application of the composition for forming a resist underlayer film is not particularly limited, and the application can be performed by an appropriate method such as spin coating, cast coating, or roll coating, and a coating film can thereby be formed.

Examples of the case where the composition for forming a resist underlayer film is applied indirectly to the substrate include a case where the composition for forming a resist underlayer film is applied to a silicon-containing film described later formed on the substrate.

### [Heating Step]

In this step, the coating film obtained by the applying step is heated at a heating temperature of higher than 450° C. and 600° C. or lower in an atmosphere having an oxygen concentration of less than 0.01% by volume.

The heating of the coating film is performed under a low-oxygen atmosphere. The heating temperature is higher than 450° C., preferably 460° C. or higher, and more preferably 480° C. or higher. The heating temperature is 600° C. or lower, preferably 550° C. or lower, and more preferably 520° C. or lower. When the heating temperature is within the above range, the resist underlayer film can be sufficiently baked and hardened, and heat resistance can be improved. The lower limit of a heating time is preferably 15 seconds, more preferably 30 seconds, and still more preferably 45 seconds. The upper limit of the heating time is preferably 1,200 seconds, more preferably 600 seconds, and still more preferably 300 seconds.

The oxygen concentration during the heating is less than 0.01% by volume, preferably 0.008% by volume or less, more preferably 0.006% by volume or less, still more preferably 0.004% by volume or less, and particularly preferably 0.003% by volume or less. When the oxygen concentration during the heating is within the above range, oxidation of the resist underlayer film can be inhibited, and characteristics required as a resist underlayer film can be suitably exhibited.

The atmosphere in which the heating of the coating film is performed is not particularly limited as long as the oxygen concentration described above is satisfied, but is preferably a nitrogen atmosphere.

The coating film may be heated under conditions different from those of the heating step. The heating temperature is preferably 90° C. or higher. The heating temperature is preferably 400° ° C. or lower. The atmosphere during the heating may be either a low-oxygen atmosphere or the air atmosphere. The lower limit of the heating time is preferably 15 seconds, more preferably 30 seconds, and still more preferably 45 seconds. The upper limit of the heating time is preferably 1, 200 seconds, more preferably 600 seconds, and still more preferably 300 seconds. After the applying step, the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 30 nm, more preferably 50 nm, and still more preferably 100 nm. The upper limit of the average thickness is preferably 3,000 nm, more preferably 2,000 nm, and still more preferably 500 nm. The average thickness is measured as described in Examples.

### <<Composition for Forming Resist Underlayer Film>>

The composition for forming a resist underlayer film includes the compound [A], the polymer [B], and the solvent [C]. The content of the polymer [B] in the composition for forming a resist underlayer film is less than the content of the compound [A]. The composition for forming a resist underlayer film may contain an optional component other than the compound [A], the polymer [B], and the solvent [C] (hereinafter also simply referred to as “other optional component”) as long as the effect of the present invention is not impaired. Examples of such other optional components include an acid generator (hereinafter also referred to as “acid generator [D]”), a crosslinking agent (hereinafter also referred to as “crosslinking agent [E]”), an oxidizing agent (hereinafter also referred to as “oxidizing agent [F]”), a surfactant, an adhesion aid, and other polymers as additives.

Setting the composition of the composition for forming a resist underlayer film as described above makes it possible to form a resist underlayer film excellent in heat resistance and flatness. The reason for this is not necessarily clear, but can be inferred as follows, for example. That is, it is considered that by using the compound [A] in combination with the polymer [B] which thermally decomposes at least at the heating temperature in the heating step and controlling the relative amounts of the compound [A] and the polymer [B], the fluidity and compatibility of each component are improved, and since the polymer [B] is thermally decomposed and disappears during the heating step, so that undesired film decomposition in the subsequent steps can be inhibited, and as a result, the heat resistance and flatness of a resist underlayer film formed of the composition for forming a resist underlayer film can be improved.

### [Compound [A]]

The compound [A] is a compound having an aromatic ring. The compound [A] to be used is not particularly limited as long as the compound has an aromatic ring and has a molecular weight of 400 or more. The compound [A] to be used may be only one kind of compound [A] or a combination of two or more kinds of compound [A]s.

The compound [A] may be either a polymer having a structural unit containing an aromatic ring (hereinafter also referred to as “[A] polymer”) or a compound that is not a polymer (namely, an aromatic ring-containing compound). In the present specification, the “polymer” refers to a compound having two or more structural units (repeating units), and the “aromatic ring-containing compound” refers to a compound that does not correspond to the polymer among compounds containing an aromatic ring.

Examples of the aromatic ring include:
an aromatic hydrocarbon ring such as a benzene ring, a naphthalene ring, an anthracene ring, an indene ring, a pyrene ring, a coronene ring, a fluorene ring, a fluorenylidenebiphenyl ring, a fluorenylidenebinaphthalene ring, a chrysene ring, a dibenzochrysene ring, or a combination thereof; and
an aromatic heterocyclic ring such as a furan ring, a pyrrole ring, an indole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine ring, or a combination thereof.

The aromatic ring also includes an aromatic cyclic amide structure obtained by reacting an aromatic dicarboxylic acid or an aromatic dicarboxylic anhydride with an aromatic amine.

The lower limit of the molecular weight of the compound [A] is preferably 400. In the present specification, the “molecular weight of the compound [A]” refers to a polystyrene-equivalent weight-average molecular weight (hereinafter also referred to as “Mw”) measured by gel permeation chromatography (GPC) under the conditions described later when the compound [A] is a [A] polymer, and refers to a molecular weight calculated from the structural formula when the compound [A] is an aromatic ring-containing compound.

When the compound [A] is an aromatic ring-containing compound, the aromatic ring-containing compound has one kind or two or more kinds of the aromatic rings repeatedly or in combination. In addition to a single bond, a divalent hydrocarbon group, —CO—, —NR′—, —O—, or a combination thereof may be present between aromatic rings. R′ is a hydrogen atom or a monovalent hydrocarbon group having 1 to 10 carbon atoms. When the compound [A] is an aromatic ring-containing compound, the lower limit of the molecular weight of the compound [A] is preferably 450, more preferably 500, still more preferably 550, and particularly preferably 600. The upper limit of the molecular weight of the compound [A] is preferably 1, 500, more preferably 1,200, still more preferably 1,000, and particularly preferably 800.

The compound [A] is preferably a [A] polymer. By use of the polymer [A] as the compound [A] in the composition, the coatability of the composition can be improved.

Examples of the [A] polymer include a polymer having an aromatic ring in the main chain and a polymer having no aromatic ring in the main chain and having an aromatic ring in a side chain. The “main chain” refers to the longest chain constituted from atoms in the polymer. The “side chain” refers to a chain other than the longest chain constituted from atoms in the polymer.

Examples of the [A] polymer include a polycondensation compound and a compound obtained by a reaction other than polycondensation.

Examples of the [A] polymer include a novolac resin, a resol resin, a styrene resin, an acenaphthylene resin, an indene resin, an arylene resin, a triazine resin, a calixarene resin, and a polyamide resin.

### (Novolac Resin)

The novolac resin is a resin obtained by reacting a phenolic compound and an aldehyde or a divinyl compound using an acidic catalyst. Two or more phenolic compounds and an aldehyde or a divinyl compound may be reacted by mixing them.

Examples of the phenolic compound include: phenols such as phenol, cresol, xylenol, resorcinol, bisphenol A, p-tert-butylphenol, p-octylphenol, 9,9-bis(4-hydroxyphenyl) fluorene, 9,9-bis(3-hydroxyphenyl)fluorene and 4,4′-(α-methylbenzylidene)bisphenol; naphthols such as α-naphthol, β-naphthol, 1,5-dihydroxynaphthalene, 2,7-dihydroxynaphthalene, 2,6-naphthalene diol and 9,9-bis(6-hydroxynaphthyl)fluorene; anthrols such as 9-anthrol; and pyrenols such as 1-hydroxypyrene and 2-hydroxypyrene.

Examples of the aldehyde include: aldehydes such as formaldehyde, benzaldehyde, 1-naphthaldehyde, 2-naphthaldehyde, 1-formylpyrene and 4-biphenylaldehyde; and aldehyde sources such as paraformaldehyde and trioxane.

Examples of the divinyl compound include divinylbenzene, dicyclopentadiene, tetrahydroindene, 4-vinylcyclohexene, 5-vinylnorbornan-2-ene, divinylpyrene, limonene, and 5-vinylnorbornadiene.

Examples of the novolac resin include a resin having structural units derived from phenol and formaldehyde, a resin having structural units derived from cresol and formaldehyde, a resin having structural units derived from dihydroxynaphthalene and formaldehyde, a resin having structural units derived from fluorene bisphenol and formaldehyde, a resin having structural units derived from fluorene bisnaphthol and formaldehyde, a resin having structural units derived from hydroxypyrene and formaldehyde, a resin having structural units derived from hydroxypyrene and naphthaldehyde, a resin having structural units derived from 4,4′-(α-methylbenzylidene)bisphenol and formaldehyde, a resin having structural units derived from a phenol compound and formylpyrene, a resin obtained by combining these resins, and a resin obtained by substituting a part or all of the hydrogen atoms of the phenolic hydroxy groups of such a resin with propargyl groups or the like.

### (Resol Resin)

The resol resin is a resin obtained by reacting a phenolic compound and an aldehyde using an alkaline catalyst.

### (Styrene Resin)

The styrene resin is a resin having a structural unit derived from a compound having an aromatic ring and a polymerizable carbon-carbon double bond. The styrene resin may have, in addition to the above structural unit, a structural unit derived from an acrylic monomer, a vinyl ether, or the like.

Examples of the styrene resin include polystyrene, polyvinyl naphthalene, polyhydroxystyrene, polyphenyl (meth)acrylate, and a combination of two or more of these resins.

### (Acenaphthylene Resin)

The acenaphthylene resin is a resin having a structural unit derived from a compound having an acenaphthylene skeleton.

Examples of the acenaphthylene resin include a copolymer of acenaphthylene and hydroxymethylacenaphthylene.

### (Indene Resin)

The indene resin is a resin having a structural unit derived from a compound having an indene skeleton.

### (Arylene Resin)

The arylene resin is a resin having a structural unit derived from a compound having an arylene skeleton. Examples of the arylene skeleton include a phenylene skeleton, a naphthylene skeleton, and a biphenylene skeleton.

Examples of the arylene resin include a polyarylene ether, a polyarylene sulfide, a polyarylene ether sulfone, a polyarylene ether ketone, a resin having a structural unit containing a biphenylene skeleton, and a resin having a structural unit containing a biphenylene skeleton and a structural unit derived from a compound containing an acenaphthylene skeleton.

### (Triazine Resin)

The triazine resin is a resin having a structural unit derived from a compound having a triazine skeleton.

Examples of the compound having a triazine skeleton include a melamine compound and a cyanuric acid compound.

When the [A] polymer is a novolac resin, a resol resin, a styrene resin, an acenaphthylene resin, an indene resin, an arylene resin, or a triazine resin, the lower limit of the Mw of the [A] polymer is preferably 1,000, more preferably 2,000, still more preferably 3,000, and particularly preferably 4,000. The upper limit of the Mw is preferably 100,000, more preferably 60,000, still more preferably 30,000, and particularly preferably 15,000. When the Mw of the [A] polymer is within the above range, the flatness of the resist underlayer film can be further improved.

The upper limit of Mw/Mn (Mn is the polystyrene-equivalent number-average molecular weight measured by GPC) of the [A] polymer is preferably 5, more preferably 3, and still more preferably 2. The lower limit of the Mw/Mn is usually 1, and preferably 1.2.

In the present specification, the method for measuring Mw and Mn of a polymer is as described in Examples.

### (Calixarene Resin)

A calixarene resin is a cyclic oligomer in which aromatic rings, to which a hydroxy group is bonded, are bonded via hydrocarbon groups to be cyclic or such a cyclic oligomer in which some or all of hydrogen atoms in the hydroxy groups, aromatic rings, and hydrocarbon groups are substituted.

Examples of the calixarene resin include a cyclic 4- to 12-mer formed from a phenolic compound such as phenol or naphthol and formaldehyde, a cyclic 4- to 12-mer formed from a phenolic compound such as phenol or naphthol and a benzaldehyde compound, and a resin obtained by substituting hydrogen atoms in phenolic hydroxy groups of such a cyclic 4- to 12-mer with propargyl groups or the like.

The lower limit of the molecular weight of the calixarene resin is preferably 500, more preferably 700, and still more preferably 1,000. The upper limit of the molecular weight is preferably 5,000, more preferably 3,000, and still more preferably 1,500.

### (Polyamide Resin)

The polyamide resin is a resin obtained by a polycondensation reaction of a carboxylic acid or an acid anhydride with an amine. The lower limit of the molecular weight of the polyamide resin is preferably 800, more preferably 1,000, and still more preferably 2,000. The upper limit of the molecular weight is preferably 10,000, more preferably 8,000, and still more preferably 6,000.

The lower limit of the content of the compound [A] is preferably 80% by mass, more preferably 85% by mass, still more preferably 90% by mass, and particularly preferably 95% by mass with respect to the total amount (total solid content) of the components other than the solvent [C] in the composition for forming a resist underlayer film. The upper limit of the content is preferably 99% by mass. The compound [A] to be used may be only one kind of compound [A] or a combination of two or more kinds of compound [A]s.

### (Method for Synthesizing Compound [A])

The compound [A] can be synthesized by a known method. A commercially available product may be used.

### [Polymer [B]]

The polymer [B] is a polymer that thermally decomposes at least at the heating temperature in the heating step (excluding the compound having an aromatic ring). In the present specification, the “polymer that thermally decomposes” refers to a polymer whose weight disappears by 95% or more when thermogravimetric measurement (TGA) is performed in a nitrogen atmosphere under the condition specified by a temperature raising rate of 10° C./min and a temperature range of higher than 450° C. and 600° C. or lower.

Examples of the polymer [B] include an acrylic polymer, a polycarbonate-based polymer, a cycloolefin-based polymer, a cellulose-based polymer, and a polyvinyl alcohol-based polymer. These materials may be used alone or two or more thereof may be used in combination. Among them, an acrylic polymer is preferable from the viewpoint of having high thermal decomposability.

### (Acrylic Polymer)

The polymer [B] as an acrylic polymer preferably has a first structural unit (hereinafter also referred to as structural unit (I)). The polymer [B] may contain, in addition to the structural unit (I), a second structural unit (hereinafter also referred to as structural unit (II)) or other structural unit (hereinafter also simply referred to as “other structural unit”). The polymer [B] may have one type or two or more types of the respective structural units.

### (Structural Unit (I))

The structural unit (I) is a structural unit represented by formula (B1). Owing to that the polymer [B] has the structural unit (I), the fluidity with the composition for forming a resist underlayer film can be improved, and as a result, the heat resistance and flatness of a resist underlayer film formed of the composition for forming a resist underlayer film can be improved.

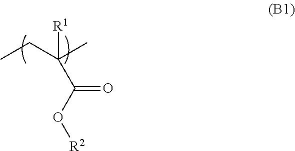

in the formula (B1), R¹ is a hydrogen atom, a halogen atom, or a monovalent organic group having 1 to 20 carbon atoms; and R² is a monovalent organic group having 1 to 20 carbon atoms.

Examples of the monovalent organic groups having 1 to 20 carbon atoms represented by R¹ and R² include a monovalent hydrocarbon group having 1 to 20 carbon atoms, a group that includes a divalent hetero atom-containing group between two adjacent carbon atoms of the aforementioned monovalent hydrocarbon group, and groups obtained by substituting a part or all of the hydrogen atoms of the aforementioned groups with monovalent heteroatom-containing groups. Examples of the divalent heteroatom-containing group include —O—, —CO—, and —COO—. Examples of the monovalent heteroatom-containing group include a hydroxy group, a halogen atom, a cyano group, and a nitro group.

In the present specification, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of the monovalent hydrocarbon group having 1 to 20 carbon atoms in R¹ or R² include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include alkyl groups such as a methyl group, an ethyl group, a propyl group, a butyl group, and a pentyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic hydrocarbon groups such as a norbornyl group and an adamantyl group.

Examples of the monovalent aromatic hydrocarbon group having 6 to 20 carbon atoms include aryl groups such as a phenyl group and a naphthyl group; and aralkyl groups such as a benzyl group, a phenethyl group, and a naphthylmethyl group.

When R¹ or R² has a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, and a nitro group.

As R¹, a hydrogen atom or a substituted or unsubstituted monovalent chain hydrocarbon group having 1 to 20 carbon atoms is preferable, a hydrogen atom or an unsubstituted monovalent hydrocarbon group having 1 to 20 carbon atoms is more preferable, and a hydrogen atom or a methyl group is still more preferable.

As R², a substituted monovalent chain hydrocarbon group having 1 to 20 carbon atoms is preferable, a fluorine atom-substituted monovalent chain hydrocarbon group having 1 to 20 carbon atoms is more preferable, and a hexafluoroisopropyl group, a 2,2,2-trifluoroethyl group, or a 3,3,4,4,5,5,6,6-octafluorohexyl group is still more preferable. In this case, the flatness of a resist underlayer film formed of the composition for forming a resist underlayer film can be further improved. In the present specification, the “fluorine atom-substituted monovalent chain hydrocarbon group having 1 to 20 carbon atoms” means a group in which a part or all of hydrogen atoms of a chain hydrocarbon group having 1 to 20 carbon atoms are substituted with fluorine atoms.

The lower limit of the content ratio of the structural unit (I) in the polymer [B] is preferably 1 mol %, more preferably 15 mol %, and still more preferably 25 mol % with respect to all structural units constituting the polymer [B]. The upper limit of the content ratio is preferably 99 mol %, more preferably 85 mol %, and still more preferably 75 mol %. When the content ratio of the structural unit (I) is within the above range, the flatness of a resist underlayer film formed of the composition for forming a resist underlayer film can be further improved.

### (Structural Unit (II))

The structural unit (II) is a structural unit represented by formula (B2). Owing to that the polymer [B] has the structural unit (II), the compatibility with the compound [A] can be improved, and as a result, the heat resistance and flatness of a resist underlayer film formed of the composition for forming a resist underlayer film can be improved.

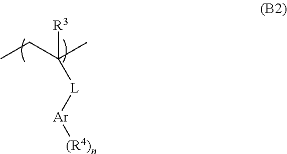

In the formula (B2), R³ is a hydrogen atom or a substituted or unsubstituted monovalent hydrocarbon group having 1 to 20 carbon atoms. L is a single bond or a divalent linking group. Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 1 to 8. When n is 2 or more, a plurality of R⁴s are the same or different from each other.

Examples of the monovalent hydrocarbon group having 1 to 20 carbon atoms in R³ include groups the same as those disclosed as examples of the monovalent hydrocarbon group having 1 to 20 carbon atoms in R¹ of the above formula (1).

When R³ has a substituent, examples of the substituent include groups the same as those disclosed as examples of the substituent in R¹ of the above formula (B1).

As R³, a hydrogen atom or a substituted or unsubstituted monovalent chain hydrocarbon group having 1 to 20 carbon atoms is preferable, a hydrogen atom or an unsubstituted monovalent chain hydrocarbon group having 1 to 20 carbon atoms is more preferable, and a hydrogen atom or a methyl group is still more preferable.

Examples of the divalent linking group in L include divalent hydrocarbon groups having 1 to 10 carbon atoms, —COO—, —CO—, —O—, and —CONH—.

A single bond is preferable as L.

Examples of the aromatic ring having 6 to 20 ring members in Ar include groups the same as those disclosed as examples of the aromatic ring of the compound [A] described above. In the present specification, the term “ring members” refers to the number of the atoms constituting the ring, and in the case of a polycyclic ring, it refers to the number of the atoms constituting the polycyclic ring.

When Ar has a substituent, examples of the substituent include groups the same as those disclosed as examples of the substituent in R¹ of the above formula (B1). However, R⁴ described later is not regarded as a substituent in Ar.

As Ar, a group obtained by removing (n+1) hydrogen atoms from an unsaturated aromatic ring having 6 to 20 ring members is preferable, a group obtained by removing (n+1) hydrogen atoms from an unsaturated aromatic hydrocarbon ring having 6 to 20 ring members is more preferable, and a group obtained by removing (n+1) hydrogen atoms from an unsubstituted benzene ring is still more preferable.

The monovalent hydroxyalkyl group having 1 to 10 carbon atoms in R⁴ is a group in which a part or all of hydrogen atoms of a monovalent alkyl group having 1 to 10 carbon atoms are substituted with hydroxy groups.

As R⁴, a monovalent hydroxyalkyl group having 1 to 10 carbon atoms is preferable, a monovalent monohydroxyalkyl group having 1 to 10 carbon atoms is more preferable, and a monohydroxymethyl group is still more preferable. Owing to that R⁴ is the above group, the flatness of a resist underlayer film formed of the composition for forming a resist underlayer film can be further improved.

n is preferably 1 to 5, more preferably 1 to 3, still more preferably 1 or 2, and particularly preferably 1.

The lower limit of the content ratio of the structural unit (II) in the polymer [B] is preferably 1 mol %, more preferably 15 mol %, and still more preferably 25 mol % with respect to all structural units constituting the polymer [B]. The upper limit of the content ratio is preferably 99 mol %, more preferably 85 mol %, and still more preferably 75 mol %. When the content ratio of the structural unit (II) is within the above range, the flatness of a resist underlayer film formed of the composition for forming a resist underlayer film can be further improved.

### (Other Structural Unit)

Examples of the other structural unit include a structural unit derived from a (meth)acrylic acid ester, a structural unit derived from a (meth)acrylic acid, and a structural unit derived from an acenaphthylene compound.

When the polymer [B] has such other structural unit, the upper limit of the content ratio of the other structural unit is preferably 20 mol %, and more preferably 5 mol % with respect to all structural units constituting the polymer [B].

### (Polycarbonate-Based Polymer)

Examples of the polycarbonate-based polymer as the polymer [B] include an aliphatic polycarbonate-based polymer which contains no aromatic compound (for example, a benzene ring) between carbonate ester groups (—O—CO—O—) of the main chain and is composed of an aliphatic chain, and an aromatic polycarbonate-based polymer which contains an aromatic compound between carbonate ester groups (—O—CO—O—) of the main chain. Among them, an aliphatic polycarbonate-based polymer is preferable. Examples of the aliphatic polycarbonate-based polymer include polyethylene carbonate and polypropylene carbonate. Examples of the aromatic polycarbonate-based polymer include those containing a bisphenol A structure in the main chain.

The lower limit of the Mw of the polymer [B] is preferably 1,000, more preferably 2,000, still more preferably 3,000, and particularly preferably 3,500. The upper limit of the Mw is preferably 100,000, more preferably 50,000, still more preferably 30,000, and particularly preferably 20,000. When the Mw of the polymer [B] is within the above range, the heat resistance and flatness of the resist underlayer film can be further improved.

The upper limit of the Mw/Mn of the polymer [B] is preferably 5, more preferably 3, and still more preferably 2.5. The lower limit of the Mw/Mn is usually 1, and preferably 1.2.

The content of the polymer [B] in the composition for forming a resist underlayer film is less than the content of the compound [A]. The content is preferably 0.1 parts by mass or more and 50 parts by mass or less based on 100 parts by mass of the compound [A]. The lower limit of the content of the polymer [B] is more preferably 0.5 parts by mass, still more preferably 1 part by mass, and particularly preferably 2 parts by mass based on 100 parts by mass of the compound [A]. The upper limit of the content is more preferably 40 parts by mass, still more preferably 30 parts by mass, and particularly preferably 25 parts by mass. When the content of the polymer [B] is within the above range, the heat resistance and flatness of a resist underlayer film formed of the composition for forming a resist underlayer film can be further improved.

### (Method for Synthesizing Polymer [B])

When the polymer [B] is an acrylic polymer, the polymer can be synthesized, for example, by polymerizing, by a known method, a monomer to afford the structural unit (I) together with, as necessary, a monomer to afford the structural unit (II) and a monomer to afford another structural unit each in a use amount leading to a prescribed content ratio.

### [Solvent [C]]

The composition for forming a resist underlayer film contains the solvent [C]. The solvent [C] is not particularly limited as long as the solvent can dissolve or disperse the compound [A], the polymer [B], and optional components contained as necessary.

Examples of the solvent [C] include alcohol-based solvents, ketone-based solvents, amide-based solvents, ether-based solvents, and ester-based solvents. The solvent [C] to be used may be only one kind of solvent [C] or a combination of two or more kinds of solvent [C]s.

Examples of the alcohol-based solvent include:
monohydric alcohol-based solvents such as methanol, ethanol, n-propanol, iso-propanol, n-butanol, iso-butanol, sec-butanol, t-butanol, n-pentanol, iso-pentanol, sec-pentanol, and t-pentanol; and
polyhydric alcohol-based solvents such as ethylene glycol, 1,2-propylene glycol, 1,3-butylene glycol, 2,4-pentanediol, 2-methyl-2,4-pentanediol, 2,5-hexanediol, and 2,4-heptanediol.

Examples of the ketone-based solvent include aliphatic ketone-based solvents such as acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, di-iso-butyl ketone, and trimethylnonanone;
cyclic ketone-based solvents such as cyclopentanone, cyclohexanone, cycloheptanone, cyclooctanone, and methylcyclohexanone; and
2,4-pentanedione, acetonylacetone, diacetone alcohol, acetophenone, and methyl n-amyl ketone.

Examples of the amide-based solvent include:
cyclic amide-based solvents such as 1,3-dimethyl-2-imidazolidinone and N-methyl-2-pyrrolidone; and
chain amide-based solvents such as formamide, N-methylformamide, N,N-dimethylformamide, N,N-diethylformamide, acetamide, N-methylacetamide, N,N-dimethylacetamide, and N-methylpropionamide.

Examples of the ether-based solvent include:
polyhydric alcohol (partial) ether-based solvents such as ethylene glycol monomethyl ether, ethylene glycol monoethyl ether, ethylene glycol dimethyl ether, and diethylene glycol dibutyl ether;
polyhydric alcohol partial ether acetate-based solvents such as ethylene glycol monomethyl ether acetate, ethylene glycol monoethyl ether acetate, propylene glycol monomethyl ether acetate (PGMEA), and propylene glycol monoethyl ether acetate;
dialiphatic ether-based solvents such as diethyl ether, dipropyl ether, dibutyl ether, butyl methyl ether, butyl ethyl ether, and diisoamyl ether;
aliphatic-aromatic ether-based solvents such as anisole and phenyl ethyl ether; and
cyclic ether-based solvents such as tetrahydrofuran, tetrahydropyran, and dioxane.

Examples of the ester-based solvent include:
carboxylic acid ester-based solvents such as methyl lactate, ethyl lactate, methyl acetate, ethyl acetate, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, and ethyl acetoacetate;
lactone-based solvents such as γ-butyrolactone and γ-valerolactone;
polyhydric alcohol acetate-based solvents such as 1,6-diacetoxyhexane; and
carbonate-based solvents such as diethyl carbonate and propylene carbonate.

Among them, the ether-based solvent, the ketone-based solvent, and the ester-based solvent are preferable. As the ether-based solvent, the polyhydric alcohol (partial) ether-based solvents, the polyhydric alcohol partial ether acetate-based solvents, and the dialiphatic ether-based solvents are preferable, the polyhydric alcohol (partial) ether-based solvents and the polyhydric alcohol partial ether acetate-based solvents are more preferable, diethylene glycol dibutyl ether and propylene glycol monoalkyl ether acetate are still more preferable, and PGMEA is particularly preferable. As the ketone-based solvent, the cyclic ketone-based solvents are preferable, and cyclohexanone and cyclopentanone are more preferable. As the ester-based solvent, the carboxylic acid ester-based solvents, the polyhydric alcohol acetate-based solvents, and the lactone-based solvent are preferable, and 1,6-diacetoxyhexane and γ-butyrolactone are more preferable.

It is preferable that the polyhydric alcohol partial ether acetate-based solvents, particularly, propylene glycol monoalkyl ether acetate, especially PGMEA is contained in the solvent [C] because the applicability of the composition for forming a resist underlayer film to a substrate such as a silicon wafer can be improved. Since the compound [A] contained in the composition for forming a resist underlayer film has high solubility in PGMEA or the like, the composition (I) for forming a resist underlayer film can exhibit excellent applicability thanks to including a polyhydric alcohol partial ether acetate-based solvent as the solvent [C], and as a result, the flatness of the resist underlayer film can be further improved. The lower limit of the content of the polyhydric alcohol partial ether acetate-based solvent in the solvent [C] is preferably 20% by mass, more preferably 60% by mass, still more preferably 90% by mass, and particularly preferably 100% by mass.

### [[D] Acid Generator]

The [D] acid generator is a component that generates an acid by the action of heat or light and promotes crosslinking of the compound [A]. When the composition for forming a resist underlayer film contains the [D] acid generator, a crosslinking reaction of the compound [A] is promoted, so that the hardness of a film to be formed can be further increased. The [D] acid generator to be used may be only one kind of [D] acid generator or a combination of two or more kinds of [D] acid generators.

Examples of the [D] acid generator include an onium salt compound and an N-sulfonyloxyimide compound.

Examples of the onium salt compound include sulfonium salts, tetrahydrothiophenium salts, iodonium salts, and ammonium salts.

Examples of the sulfonium salts include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenylenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, and 4-methanesulfonylphenyldiphenylsulfonium 2-bicyclo[2.2.1]hept-2-yl-1,1,2,2-tetrafluoroethanesulfonate.

Examples of the tetrahydrothiophenium salts include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, and 1-(3,5-dimethyl-4-hydroxyphenyl)tetrahydrothiophenium 2-bicyclo[2.2.1]hept-2-yl-1,1,2,2-tetrafluoroethanesulfonate.

Examples of the iodonium salts include:
diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate;
diphenyliodonium trifluoromethanecarboxylate, diphenyliodonium nonafluoro-n-butanecarboxylate, diphenyliodonium perfluoro-n-octanecarboxylate, diphenyliodonium 2-bicyclo[2.2.1]hept-2-yl-1,1,2,2-tetrafluoroethanecarboxylate, bis(4-t-butylphenyl)iodonium trifluoromethanecarboxylate, bis(4-t-butylphenyl)iodonium nonafluoro-n-butanecarboxylate, bis(4-t-butylphenyl)iodonium perfluoro-n-octanecarboxylate, and bis(4-t-butylphenyl)iodonium 2-bicyclo[2.2.1]hept-2-yl-1,1,2,2-tetrafluoroethanecarboxylate.

Examples of the N-sulfonyloxyimide compound include N-(trifluoromethanesulfonyloxy)bicyclo[2.2.1]hept-5-ene-2,3-dicarboximide, N-(nonafluoro-n-butanesulfonyloxy)bicyclo[2.2.1]hept-5-ene-2,3-dicarboximide, N-(perfluoro-n-octanesulfonyloxy)bicyclo[2.2.1]hept-5-ene-2,3-dicarboximide, and N-(2-bicyclo[2.2.1]hept-2-yl-1,1,2,2-tetrafluoroethanesulfonyloxy)bicyclo[2.2.1]hept-5-ene-2,3-dicarboximide.

Examples of the ammonium salts include tripropylammonium trifluoromethanesulfonate, tripropylammonium nonafluoro-n-butanesulfonate, tripropylammonium perfluoro-n-octanesulfonate, and tripropylammonium 2-bicyclo[2.2.1]hept-2-yl-1,1,2,2-tetrafluoroethanesulfonate.

Among them, the [D] acid generator is preferably an onium salt compound, more preferably an iodonium salt, and still more preferably bis(4-t-butylphenyl)iodonium nonafluoro-n-butanesulfonate.

When the composition for forming a resist underlayer film contains the [D] acid generator, the lower limit of the content of the [D] acid generator is preferably 0.1 parts by mass, more preferably 1 part by mass, and still more preferably 2 parts by mass based on 100 parts by mass of the compound [A]. The upper limit of the content is preferably 20 parts by mass, more preferably 10 parts by mass, and still more preferably 8 parts by mass. When the content of the [D] acid generator is within the above range, a crosslinking reaction of the compound [A] can be more effectively promoted.

### ([E] Crosslinking Agent)

The [E] crosslinking agent is a component that forms a crosslinking bond between components such as the compound [A] by the action of heat or an acid. While the compound [A] may have an intermolecular bond-forming group, when the composition for forming a resist underlayer film further contains the [E] crosslinking agent, the hardness of the resist underlayer film can be increased. The [E] crosslinking agent to be used may be only one kind of [E] crosslinking agent or a combination of two or more kinds of [E] crosslinking agents.

Examples of the crosslinking agent include a polyfunctional (meth)acrylate compound, an epoxy compound, a hydroxymethyl group-substituted phenol compound, an alkoxyalkyl group-containing phenol compound, a compound having an alkoxyalkylated amino group, and compounds represented by formulas (E1) to (E5) (hereinafter, also referred to as “compounds (E1) to (E5)”).

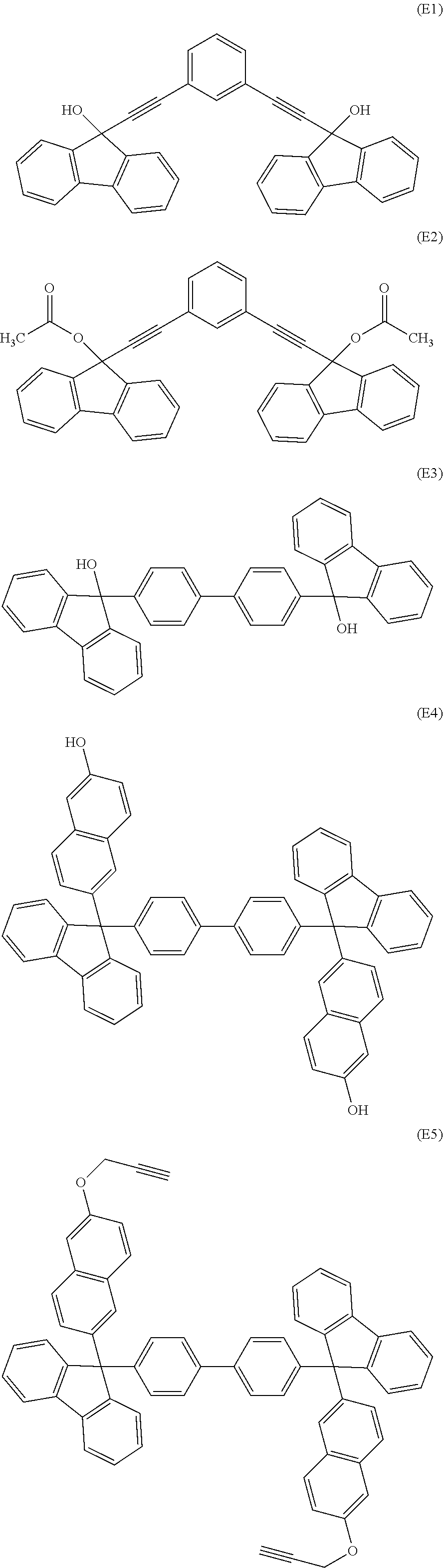 [SMILES: OC1(C#Cc2cccc(C#CC3(O)c4ccccc4-c4ccccc43)c2)c2ccccc2-c2ccccc21 ; CC(=O)OC1(C#Cc2cccc(C#CC3(OC(C)=O)c4ccccc4-c4ccccc43)c2)c2ccccc2-c2ccccc21 ; OC1(c2ccc(-c3ccc(C4(O)c5ccccc5-c5ccccc54)cc3)cc2)c2ccccc2-c2ccccc21 ; Oc1ccc2cc(C3(c4ccc(-c5ccc(C6(c7ccc8cc(O)ccc8c7)c7ccccc7-c7ccccc76)cc5)cc4)c4ccccc4-c4ccccc43)ccc2c1 ; C#CCOc1ccc2cc(C3(c4ccc(-c5ccc(C6(c7ccc8cc(OCC#C)ccc8c7)c7ccccc7-c7ccccc76)cc5)cc4)c4ccccc4-c4ccccc43)ccc2c1]

Examples of the polyfunctional (meth)acrylate compound include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, and bis(2-hydroxyethyl)isocyanurate di(meth)acrylate.

Examples of the epoxy compound include a novolac-type epoxy resin, a bisphenol-type epoxy resin, an alicyclic epoxy resin, and an aliphatic epoxy resin.

Examples of the hydroxymethyl group-substituted phenol compound include 2-hydroxymethyl-4,6-dimethylphenol, 1,3,5-trihydroxymethylbenzene, and 3,5-dihydroxymethyl-4-methoxytoluene[2,6-bis(hydroxymethyl)-p-cresol].

Examples of the alkoxyalkyl group-containing phenol compound include a methoxymethyl group-containing phenol compound and an ethoxymethyl group-containing phenol compound.

Examples of the compound having an alkoxyalkylated amino group include a compound derived from a nitrogen-containing compound having a plurality of active methylol groups in one molecule, such as (poly)methylolated melamine, (poly)methylolated glycoluril, (poly)methylolated benzoguanamine, and (poly)methylolated urea, wherein at least one hydrogen atom of the hydroxy groups of the methylol group is replaced with an alkyl group such as a methyl group or a butyl group. The compound having an alkoxyalkylated amino group may be a mixture obtained by mixing a plurality of substituted compounds, or may contain an oligomer component formed by partial self-condensation.

When the composition for forming a resist underlayer film contains the [E] crosslinking agent, the lower limit of the content of the [E] crosslinking agent is preferably 0.1 parts by mass, more preferably 0.5 parts by mass, still more preferably 1 part by mass, and particularly preferably 3 parts by mass based on 100 parts by mass of the compound [A]. The upper limit of the content is preferably 80 parts by mass, more preferably 50 parts by mass, still more preferably 30 parts by mass, and particularly preferably 20 parts by mass. When the content of the [E] crosslinking agent is within the above range, a crosslinking reaction of the compound [A] can be more effectively caused.

### [[F] Oxidizing Agent]

The [F] oxidizing agent is a component that promotes crosslinking of the compound [A] by an oxidation reaction. When the composition contains an oxidizing agent, a crosslinking reaction of the compound [A] is promoted, so that the heat resistance of a resist underlayer film to be formed can be further enhanced. The [F] oxidizing agent to be used may be only one kind of [F] oxidizing agent or a combination of two or more kinds of [F] oxidizing agents.

As the [F] oxidizing agent, a known oxidizing agent can be used. A diketone compound is preferable as the oxidizing agent, and examples thereof include 2,3-dichloro-5,6-dicyano-1,4-benzoquinone, 3,5-di-tert-butyl-1,2-benzoquinone, 2,3-butanedione, pyruvic acid, oxamide, oxamic acid, 2,3-pentanedione, 2-oxobutyric acid, methyl pyruvate, 1,2-cyclohexanedione, 3-methyl-1,2-cyclopentanedione, parabanic acid, 3,4-hexanedione, methyl 2-oxobutyrate, ethyl pyruvate, 2-oxovaleric acid, ethyl oxamate, N,N-dimethyloxamic acid, dimethyl oxalate, 3,4-dimethyl-1,2-cyclopentanedione, 2,3-heptanedione, 5-methyl-2,3-hexanedione, 4-methyl-2-oxovaleric acid, 3-methyl-2-oxovaleric acid, 3,3-dimethyl-2-oxobutyric acid, methyl 2-oxovalerate, oxalacetic acid, 1-ethyl-2,3-dioxopiperazine, butyl oxaminate, 2-oxoglutaric acid, diethyl oxalate, 1,2-indanedione, isatin, 1-phenyl-1,2-propanedione, benzoyl formate, methyl trifluoropyruvate, ethyl 2,4-dioxovalerate, 1,2-naphthoquinone, 1-methylisatin, methyl benzoylformate, phenylpyruvic acid, 2,3-bornanedione, triquinoyl hydrate, ethyl trifluoropyruvate, diethyl mesoxalate, dimethyl 2-oxoglutarate, dimethyloxaloylglycine, N,N′-dimethoxy-N,N′-dimethyloxamide, ethyl benzoylformate, 4-hydroxyphenylpyruvic acid, diethyl oxalacetate, furyl, 1,1′-oxalyldiimidazole, diethyl methyloxalacetate, dibutyl oxalate, 9,10-phenanthrenequinone, 1,10-phenanthroline-5,6-dione, benzil, diethyl chloroxalacetate, 1,3-diphenylpropanetrione, diphenyl oxalate, o-chloranil, 1,4-bisbenzil, bis(2,4-dinitrophenyl) oxalate, and bis(2,4,6-trichlorophenyl) oxalate.

When the composition for forming a resist underlayer film contains the [F] oxidizing agent, the lower limit of the content of the [F] oxidizing agent is preferably 0.01 parts by mass, more preferably 0.1 parts by mass, and still more preferably 0.5 parts by mass based on 100 parts by mass of the compound [A]. The upper limit of the content is preferably 10 parts by mass, more preferably 5 parts by mass, and still more preferably 3 parts by mass. When the content of the [F]oxidizing agent is within the above range, a crosslinking reaction of the compound [A] can be more effectively caused.

### (Surfactant)

When the composition for forming a resist underlayer film contains a surfactant, the applicability thereof can be improved, and as a result, the application surface uniformity of the underlayer film to be formed can be improved, and the occurrence of application unevenness can be inhibited. The surfactant to be used may be only one kind of surfactant or a combination of two or more kinds of surfactants.

Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of commercially available surfactant include KP341 (available from Shin-Etsu Chemical Co., Ltd.); Polyflow No. 75 and Polyflow No. 95 (each available from Kyoeisha Chemical Co., Ltd.); EFTOP EF101, EFTOP EF204, EFTOP EF303 and EFTOP EF352 (each available from Tochem Products Co. Ltd.); Megaface F171, Megaface F172 and Megaface F173 (each available from DIC Corporation); Fluorad FC430, Fluorad FC431, Fluorad FC135 and Fluorad FC93 (each available from Sumitomo 3M Limited); ASAHI GUARD AG710, Surflon S382, Surflon SC101, Surflon SC102, Surflon SC103, Surflon SC104, Surflon SC105 and Surflon SC106 (each available from Asahi Glass Co., Ltd.).

When the composition for forming a resist underlayer film contains the surfactant, the lower limit of the content of the surfactant is preferably 0.01 parts by mass, more preferably 0.05 parts by mass, and still more preferably 0.1 parts by mass based on 100 parts by mass of the compound [A]. The upper limit of the content is preferably 10 parts by mass, more preferably 5 parts by mass, and still more preferably 1 part by mass. When the content of the surfactant is within the above range, the applicability of the composition for forming a resist underlayer film can be further improved.

### (Other Polymer)

Examples of other polymer as an additive include an acrylic polymer containing only a structural unit having a phenolic hydroxy group, an acrylic polymer containing only a structural unit having an alcoholic hydroxy group, and an acrylic polymer containing a structural unit having an alcoholic hydroxy group and a structural unit having a heterocyclic structure.

### <Method for Preparing Composition for Forming Resist Underlayer Film>

The composition for forming a resist underlayer film can be prepared by mixing the compound [A], the polymer [B], the solvent [C], and as necessary, the [D] acid generator, the [E] crosslinking agent, the [F] oxidizing agent, and other components in a prescribed ratio, and preferably filtering the resulting mixture through a membrane filter having a pore size of about 0.5 μm, or the like. The lower limit of the solid concentration of the composition for forming a resist underlayer film is preferably 0.1% by mass, more preferably 1% by mass, still more preferably 2% by mass, and particularly preferably 4% by mass. The upper limit of the solid concentration is preferably 50% by mass, more preferably 30% by mass, even more preferably 15% by mass, and particularly preferably 8% by mass.

### <<Method for Manufacturing Semiconductor Substrate>>

The method for manufacturing a semiconductor substrate includes: applying a composition for forming a resist underlayer film directly or indirectly to a substrate (hereinafter also referred to as “applying step”); heating a coating film obtained by the applying step at a heating temperature of higher than 450° C. and 600° C. or lower in an atmosphere having an oxygen concentration of less than 0.01% by volume (hereinafter also referred to as “heating step”); forming a resist pattern directly or indirectly on the resist underlayer film formed by the heating step (hereinafter also referred to as “resist pattern forming step”); and performing etching using the resist pattern as a mask (hereinafter also referred to as “etching step”),

The composition for forming a resist underlayer film includes a compound having an aromatic ring, a polymer that thermally decomposes at least at the heating temperature in the heating step (excluding the compound having an aromatic ring), and a solvent, wherein the compound having an aromatic ring has a molecular weight of 400 or more, and a content of the polymer in the composition for forming a resist underlayer film is less than a content of the compound having an aromatic ring. As such a composition for forming a resist underlayer film, the composition for forming a resist underlayer film to be used in a method for forming the above-described resist underlayer film can be suitably employed.

According to the method for manufacturing a semiconductor substrate, a resist underlayer film excellent in heat resistance and flatness can be formed due to the use in the applying step of the composition for forming a resist underlayer film to be used in the method for forming a resist underlayer film described above, so that a semiconductor substrate having a favorable pattern shape can be manufactured.

The method for manufacturing a semiconductor substrate may further include, as necessary, forming a silicon-containing film directly or indirectly on the resist underlayer film before forming the resist pattern (hereinafter also referred to as “silicon-containing film forming step”).

### [Applying Step]

As this step, the applying step in the above-described method for forming a resist underlayer film can be suitably employed.

### [Heating Step]

As this step, the heating step in the above-described method for forming a resist underlayer film can be suitably employed.

### [Silicon-Containing Film Forming Step]

In this step, a silicon-containing film is formed directly or indirectly on the resist underlayer film formed through the applying step or the heating step. Examples of the case where the silicon-containing film is formed indirectly on the resist underlayer film include a case where a surface modification film of the resist underlayer film is formed on the resist underlayer film. The surface modification film of the resist underlayer film is, for example, a film having a contact angle with water different from that of the resist underlayer film.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the resist underlayer film is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film is a value measured using the spectroscopic ellipsometer in the same manner as for the average thickness of the resist underlayer film.

### [Resist Pattern Forming Step]

In this step, a resist pattern is formed directly or indirectly on the resist underlayer film. Examples of a method for performing this step include a method using a resist composition, a method using nanoimprinting, and a method using a self-assembly composition. Examples of the case of forming a resist pattern indirectly on the resist underlayer film include a case of forming a resist pattern on the silicon-containing film.

Examples of the resist composition include a positive or negative chemically amplified resist composition containing a radiation sensitive acid generator, a positive resist composition containing an alkali-soluble resin and a quinonediazide-based photosensitizer, and a negative resist composition containing an alkali-soluble resin and a crosslinking agent.

Examples of the method of applying the resist composition include a spin coating method. The temperature and time of the prebaking may be appropriately adjusted according to the type or the like of the resist composition to be used.

Then, the formed resist film is subjected to exposure by selective irradiation with radiation. Radiation to be used for the exposure can be appropriately selected according to the type or the like of the radiation-sensitive acid generator to be used in the resist composition, and examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred.

After the exposure, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include the various organic solvents recited as examples of the solvent [B] in the composition described above.

After the development with a developer, a prescribed resist pattern is formed through washing and drying.

### [Etching Step]

In this step, etching is performed using the resist pattern as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, the resist underlayer film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₃, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₃, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

### <<Composition for Forming Resist Underlayer Film>>

The composition for forming a resist underlayer film is a composition for forming a resist underlayer film suitable for a method for forming a resist underlayer film, the method including: applying a composition for forming a resist underlayer film directly or indirectly to a substrate; and heating a coating film obtained by the applying step at a heating temperature of higher than 450° C. and 600° C. or lower in an atmosphere having an oxygen concentration of less than 0.01% by volume, wherein the composition for forming a resist underlayer film includes: a compound having an aromatic ring; a polymer that thermally decomposes at least at the heating temperature in the heating step (excluding the compound having an aromatic ring); and a solvent, the compound having an aromatic ring has a molecular weight of 400 or more, and a content of the polymer is less than a content of the compound having an aromatic ring. As such a composition for forming a resist underlayer film, the composition for forming a resist underlayer film to be used in a method for forming the above-described resist underlayer film can be suitably employed. The composition for forming a resist underlayer film can form a resist underlayer film excellent in heat resistance and flatness.

### <<Resist Underlayer Film>>

The resist underlayer film is formed of the composition for forming a resist underlayer film. The resist underlayer film formed of the composition for forming a resist underlayer film is excellent in heat resistance and flatness.

### EXAMPLES

Hereinbelow, the present invention will specifically be described on the basis of examples, but is not limited to these examples.

### [Weight-Average Molecular Weight (Mw)]

The Mw of a polymer was measured by gel permeation chromatography (detector: differential refractometer) with monodisperse polystyrene standards using GPC columns (“G2000HXL”×2, “G3000HXL”×1 and “G4000HXL”×1) manufactured by Tosoh Corporation under the following analysis conditions: flow rate: 1.0 mL/min; elution solvent: tetrahydrofuran; column temperature: 40° C.

### [Average Thickness of Resist Underlayer Film]

The average thickness of a film was determined as a value obtained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### <Synthesis of Compound [A]>

Compounds or polymers represented by formulas (A-1) to (A-9) and (A-11) to (A-31) (hereinafter, also referred to as “compounds or polymers (A-1) to (A-9) and (A-11) to (A-31)”) were synthesized as the compound [A] by the procedures described below. As the compound represented by formula (A-9) (compound (A-9)), a ready-made product was used. The polymer (A-10) was a polymer having a structural unit derived from the compound (A-9).

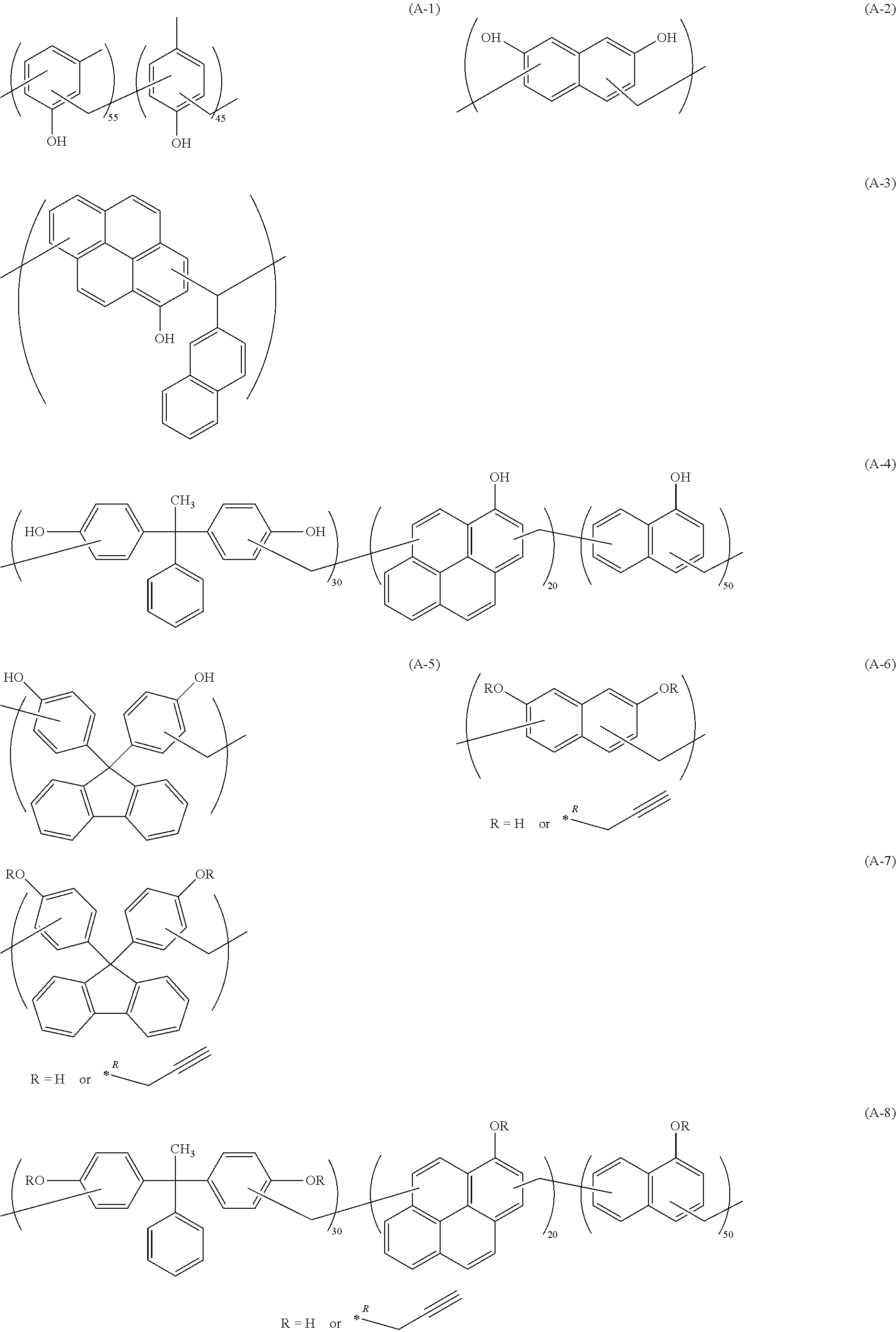

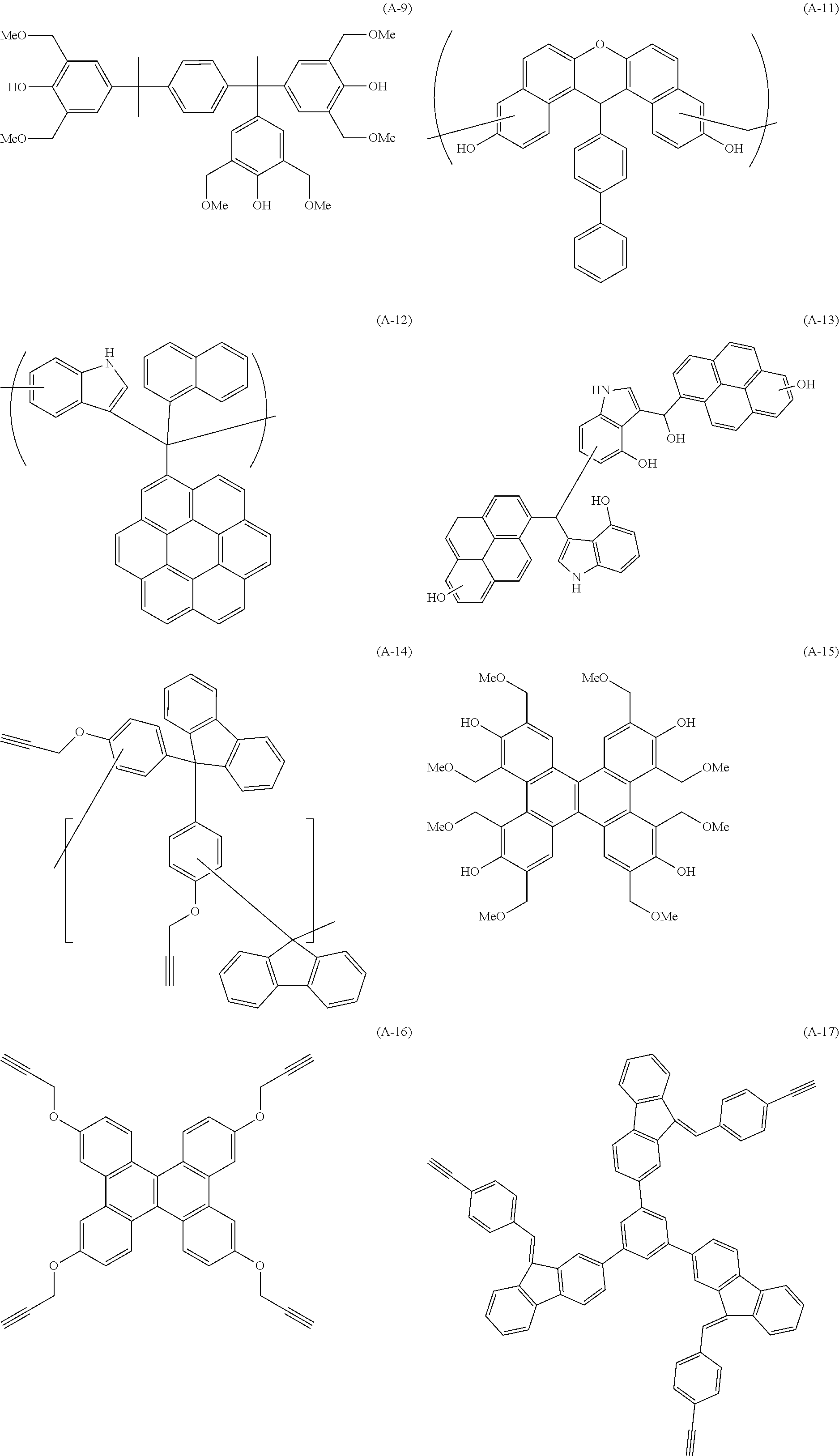

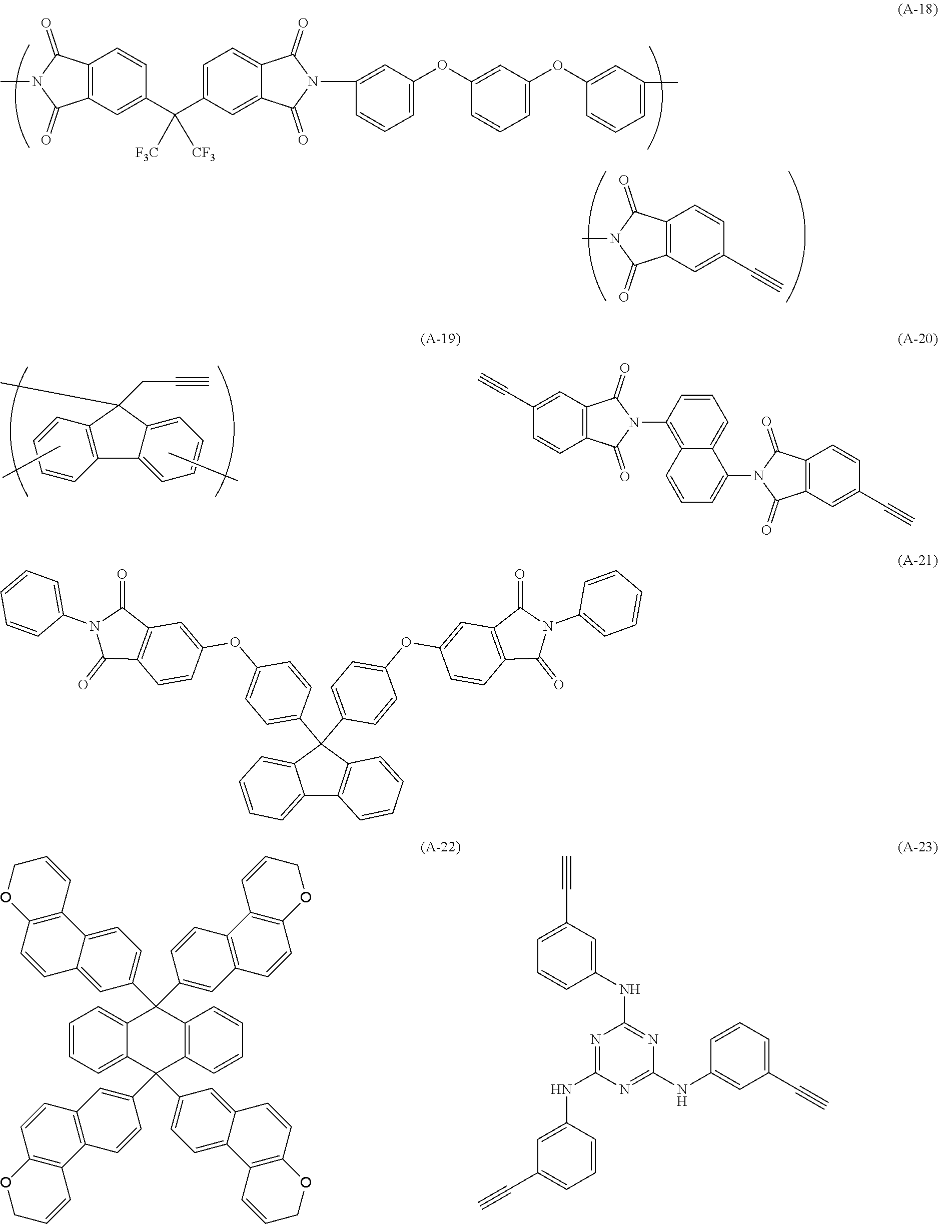

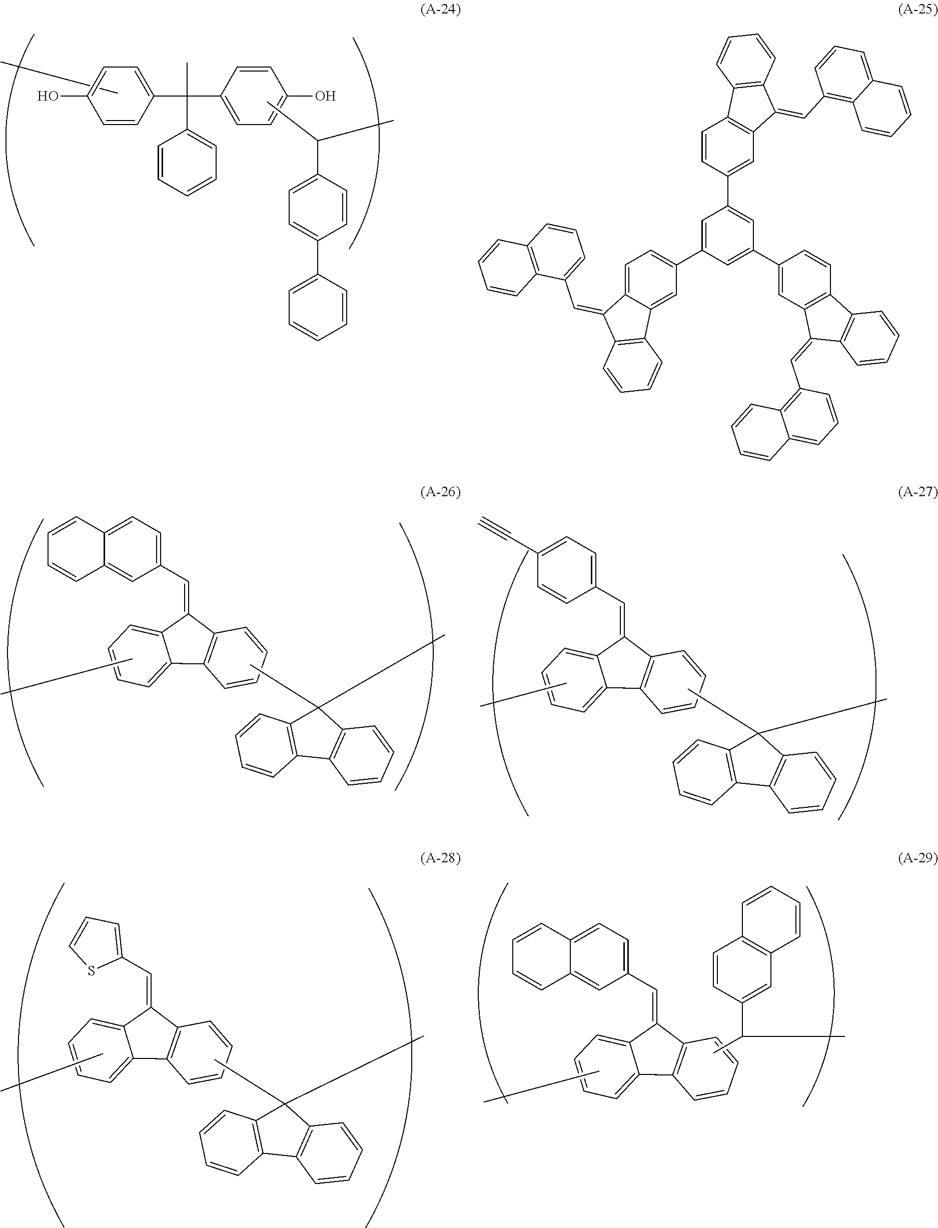

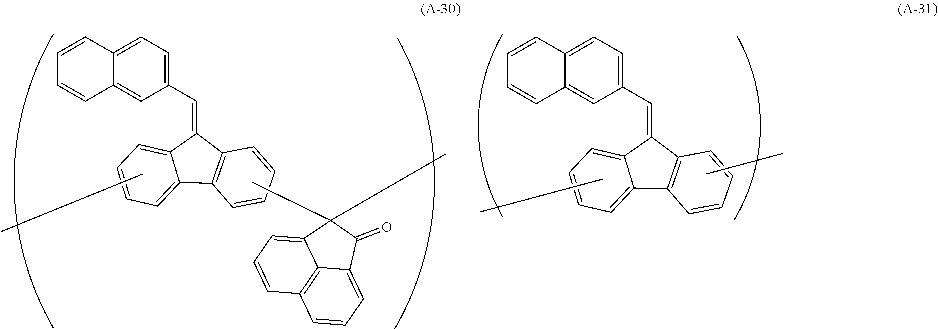

In the formulas (A-1), (A-4) and (A-8), the number attached to each structural unit indicates the content ratio (mol %) of the structural unit. In the formulas (A-6), (A-7) and (A-8), *^{R} represents a moiety bonded to an oxygen atom.

### [Synthesis Example 1-1] (Synthesis of Polymer (A-1))

In a nitrogen atmosphere, 70 g of m-cresol, 57.27 g of p-cresol, 95.52 g of a 37 mass % aqueous formaldehyde solution, and 381.82 g of methyl isobutyl ketone were added to a reaction container and dissolved. The obtained solution was heated to 40° C., 2.03 g of p-toluenesulfonic acid was then added thereto, and the resultant was reacted at 85° C. for 4 hours. The reaction liquid was cooled to 30° C. or lower and charged into a mixed solution of methanol/water (50/50 (mass ratio)) for reprecipitation. A precipitate was collected on filter paper and dried to obtain a polymer (A-1). The Mw of the polymer (A-1) was 50,000.

### [Synthesis Example 1-2] (Synthesis of Polymer (A-2))

In a nitrogen atmosphere, 150 g of 2,7-dihydroxynaphthalene, 76.01 g of a 37 mass % aqueous formaldehyde solution, and 450 g of methyl isobutyl ketone were added to a reaction container and dissolved. The obtained solution was heated to 40° C., 1.61 g of p-toluenesulfonic acid was then added thereto, and the resultant was reacted at 80° C. for 7 hours. The reaction liquid was cooled to 30° C. or lower and charged into a mixed solution of methanol/water (50/50 (mass ratio)) for reprecipitation. A precipitate was collected on filter paper and dried to obtain a polymer (A-2). The Mw of the polymer (A-2) was 3,000.

### [Synthesis Example 1-3] (Synthesis of Polymer (A-3))

Under a nitrogen atmosphere, 20 g of 1-hydroxypyrene, 7.16 g of 2-naphthaldehyde, and 82 g of propylene glycol monomethyl ether were charged into a reaction vessel, and dissolved at room temperature. To the obtained solution was added 8.81 g of methanesulfonic acid, and the mixture was stirred at 120° C. for 12 hours for polymerization. After the completion of the polymerization, a polymerization reaction liquid was charged into a large amount of a mixed solution of methanol/water (80/20 (mass ratio)), and the obtained precipitate was collected by filtration, affording polymer (A-3). The Mw of the polymer (A-3) was 1,100.

### [Synthesis Example 1-4] (Synthesis of Polymer (A-4))

Under a nitrogen atmosphere, 15.2 g of 4,4′-(α-methylbenzylidene)bisphenol, 7.63 g of 1-hydroxypyrene, 12.6 g of 1-naphthol, and 4.52 g of paraformaldehyde were charged into a reaction vessel. Then, 60 g of propylene glycol monomethyl ether acetate was added thereto for dissolution, 0.220 g of p-toluenesulfonic acid monohydrate was then added, and the resultant was stirred at 95° C. for 6 hours for polymerization. After the completion of the polymerization, a polymerization reaction liquid was charged into a large amount of a mixed solution of methanol/water (70/30 (mass ratio)), and the obtained precipitate was collected by filtration, affording polymer (A-4). The Mw of the polymer (A-4) was 3,363.

### [Synthesis Example 1-5] (Synthesis of Polymer (A-5))

Polymer (A-5) was obtained in the same manner as Synthesis Example 1-4 except that 15.12 g of 4,4′-(α-methylbenzylidene)bisphenol, 7.63 g of 1-hydroxypyrene, 12.6 g of 1-naphthol and 4.52 g of paraformaldehyde in Synthesis Example 1-4 were replaced with 37.9 g of bisphenol fluorene and 2.86 g of paraformaldehyde.

### [Synthesis Example 1-6] (Synthesis of Polymer (A-6))

In a nitrogen atmosphere, 20 g of the polymer (A-2) synthesized in Synthesis Example 1-2, 80 g of N,N-dimethylacetamide, and 22 g of potassium carbonate were charged into a reaction container. Then, the resultant was heated to 80° C., and 19 g of propargyl bromide was added thereto to perform a reaction with stirring for 6 hours. Then, 40 g of methyl isobutyl ketone and 80 g of water were added to the reaction solution to perform separation of liquids, the obtained organic phase was then charged into a large amount of methanol, and the obtained precipitate was collected by filtration to obtain a polymer (A-6). The Mw of the polymer (A-6) was 3,200.

### [Synthesis Example 1-7] (Synthesis of Polymer (A-7))

Under a nitrogen atmosphere, 20 g of the polymer (A-5) synthesized in Synthesis Example 1-5, 80 g of N,N-dimethylacetamide, and 22 g of potassium carbonate were charged into a reaction container. Then, the resultant was heated to 80° C., and 19 g of propargyl bromide was added thereto to perform a reaction with stirring for 6 hours. Then, 40 g of methyl isobutyl ketone and 80 g of water were added to the reaction solution to perform separation of liquids, the obtained organic phase was then charged into a large amount of methanol, and the obtained precipitate was collected by filtration, affording polymer (A-7). The Mw of the polymer (A-7) was 4,800.

### [Synthesis Example 1-8] (Synthesis of Polymer (A-8))

Under a nitrogen atmosphere, 20 g of the polymer (A-4) synthesized in Synthesis Example 1-4 and 18.9 g of potassium carbonate were charged into a reaction container. Then, the resultant was heated to 80° C., and 35.3 g of propargyl bromide was added thereto to perform a reaction with stirring for 6 hours. Then, 40 g of methyl isobutyl ketone and 80 g of water were added to the reaction solution to perform separation of liquids, the obtained organic phase was then charged into a large amount of methanol, and the obtained precipitate was collected by filtration, affording polymer (A-8). The Mw of the polymer (A-8) was 3,820.

### [Synthesis Example 1-9] (Synthesis of Polymer (A-10))

In 200 g of methyl isobutyl ketone was dissolved 50.0 g of the compound (A-9). The obtained solution was heated to 40° C., 0.69 g of p-toluenesulfonic acid was then added thereto, and the resultant was reacted at 100° C. for 6 hours. The reaction solution was cooled to 30° C., 300 g of propylene glycol monomethyl ether acetate was then added, and methyl isobutyl ketone was removed by concentration under reduced pressure, affording a propylene glycol monomethyl ether acetate solution of polymer (A-10). The Mw of the polymer (A-10) was 2,400.

### [Synthesis Example 1-10] (Synthesis of Polymer (A-11))

First, 1.60 g of 2,6-naphthalenediol, 1.82 g of 4-biphenylaldehyde, and 30 ml of methyl isobutyl ketone were charged, 5 ml of 95% sulfuric acid was then added, and the mixture was reacted at 100° C. for 6 hours. Next, the reaction solution was concentrated, and 50 g of pure water was added to precipitate a reaction product. The mixture was cooled to room temperature, and then separated by filtration. The resulting solid was collected by filtration and dried, and then subjected to separation and purification by column chromatography. The compound (10 g), 0.7 g of paraformaldehyde, 50 ml of glacial acetic acid, and 50 ml of propylene glycol monomethyl ether (PGME) were charged, 8 ml of 95% sulfuric acid was added thereto, and the mixture was reacted at 100° C. for 6 hours. Next, the reaction solution was concentrated, 1000 ml of methanol was added to precipitate a reaction product, and the mixture was cooled to room temperature and then separated by filtration. The resulting solid was collected by filtration and dried, and then subjected to separation and purification by column chromatography, affording polymer (A-11). The Mw of the polymer (A-11) was 1,793.

### [Synthesis Example 1-11] (Synthesis of Polymer (A-12))

Coronene (30 g) and 19 g of 2-naphthoyl chloride were placed in a flask containing 170 g of dichloroethane, and dissolved. After 15 minutes, 16 g of aluminum trichloride was gradually added, and the mixture was reacted at normal temperature for 4 hours. After completion of the reaction, aluminum trichloride was removed using water, and the mixture was concentrated using an evaporator, affording the compound (a-12) shown below. Next, 11.7 g of 1H-indole, 45.5 g of the compound (a-12), 9.5 g of p-toluenesulfonic acid monohydrate, and 82 g of 1,4-dioxane were added to a flask, and then stirred at 100° C. After completion of the reaction, 100 g of hexane was added to extract 1,4-dioxane, then a precipitate formed by adding methanol was collected by filtration, and the remaining monomer was removed using methanol, affording polymer (A-12). The Mw of the polymer (A-12) was 2,900.

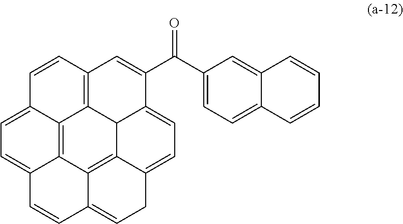 [SMILES: O=C(C1=Cc2ccc3ccc4ccc5c6c4c3c2C2C1=CC=C(CC=5)C=62)c1ccc2ccccc2c1]

### [Synthesis Example 1-12] (Synthesis of Compound (A-13))

4-Hydroxyindole (30 mmol), hydroxy-pyrene-1-carbaldehyde (30 mmol), and tetramethylguanidine (6 mmol) were added and 60 ml of distilled water was added as a solvent, and the reaction mixture was stirred at room temperature (25° C.) for 24 hours. After completion of the reaction, liquid-liquid separation-extraction was performed using distilled water and ethyl acetate, and the organic layer was collected. The collected organic layer was dissolved in 40 g of propylene glycol monomethyl ether acetate, and p-toluenesulfonic acid (10 mol % with respect to the entire reactant) was added, and then the resulting mixture was stirred and heated at 60° C. for 2 hours. After completion of the reaction, liquid-liquid separation-extraction was performed using distilled water and ethyl acetate, and the organic layer was collected. The organic layer was added dropwise to n-hexane (500 ml), followed by precipitation, filtration, and drying, and thus compound (A-13) was obtained.

### [Synthesis Example 1-13] (Synthesis of Polymer (A-14))

To a reactor were added 9-fluorenone (200 parts by mass), 9,9-bis(4-hydroxyphenyl)fluorene (2,333 parts by mass), and dichloromethane (10,430 parts by mass), and the mixture was heated to 40° C. with stirring under a nitrogen atmosphere, and that temperature was maintained. Thereafter, trifluoromethanesulfonic acid (92 parts by mass) and 3-mercaptopropionic acid (6 parts by mass) dissolved in dichloromethane (200 parts by mass) were slowly added to the reactor, and the resulting mixture was reacted with stirring at 40° C. for 2 minutes. After completion of the reaction, the reaction solution was cooled to room temperature. Sufficient water was added to the reaction solution, and excess 9,9-bis(4-hydroxyphenyl)fluorenone was removed by filtration. The precipitate was washed with dichloromethane. Sufficient water was added to the dichloromethane solution and trifluoromethanesulfonic acid was removed. Thereafter, dichloromethane was removed, affording a precursor. To a reactor were added the precursor (200 parts by mass), potassium carbonate (323 parts by mass), and acetone (616 parts by mass), and the resulting mixture was kept at 56° C. while being stirred under a nitrogen atmosphere. Thereafter, 3-bromo-1-propyne (278 parts by mass) was added to the reactor, and the mixture was held at 56° C. for 3 hours and reacted while being stirred. After completion of the reaction, the reaction solution was cooled to normal room temperature. Excess potassium carbonate and salts thereof were removed by filtration. The precipitate was washed with acetone and a dry solid was obtained. The obtained dry solid was dissolved in ethyl acetate (820 parts by mass). Sufficient water was added to the ethyl acetate solution and metal impurities were removed. Ethyl acetate was removed and a dry solid was obtained. This dry solid (185 parts by mass) was dissolved in acetone (185 parts by mass). Thereafter, methanol (1,850 parts by mass) was added to the acetone solution, and the mixture was filtered, affording a solid. The solid was dried, affording polymer (A-14). The Mw of the polymer (A-14) was 1,600.

### [Synthesis Example 1-14] (Synthesis of Compound (A-15))

Under a nitrogen atmosphere, 50.0 g of 3,6,11,14-tetrahydroxydibenzochrysene, 25.5 g of sodium hydroxide, and 200 g of water were made into a homogeneous solution at 40° C. Following dropwise addition of 61.2 g of 37% formalin over 1 hour, the resulting mixture was stirred at 40° C. for 8 hours. After adding 800 g of methyl isobutyl ketone, 120 g of a 20% aqueous hydrochloric acid solution was added with cooling in an ice bath, and the reaction was thereby stopped. After the insoluble matter was separated by filtration, the aqueous layer was removed, and the organic layer was washed 5 times with 200 g of pure water. The organic layer was dried to solidify under reduced pressure, then the residue was dissolved in 250 g of tetrahydrofuran, and the solution was charged into diisopropyl ether and reprecipitated. The precipitate was collected by filtration, washed twice with 200 g of diisopropyl ether, and then dried at 50° C. under vacuum. This compound (20.0 g) and 121.6 g of methanol were made into a homogeneous solution at 50° C. under a nitrogen atmosphere, then 6.2 g of a 10 wt % solution of sulfuric acid in methanol was slowly added dropwise, and the mixture was stirred under reflux for 8 hours. After cooling to room temperature, 300 g of methyl isobutyl ketone and 100 g of pure water were added. After the insoluble matter was separated by filtration, the aqueous layer was removed, and the organic layer was washed 5 times with 200 g of pure water. The organic layer was dried to solidify under reduced pressure, then the residue was dissolved in 60 g of toluene, and the solution was charged into hexane and reprecipitated. The precipitate was collected by filtration, washed twice with 100 g of hexane, and then dried at 50° C. under vacuum, affording compound (A-15).

### [Synthesis Example 1-15] (Synthesis of Compound (A-16))

While 39.2 g of 3,6,11,14-tetrahydroxydibenzochrysene, 66.9 g of potassium carbonate, and 180 g of dimethylformamide were stirred at 50° C. under a nitrogen atmosphere, 52.3 g of propargyl bromide was added dropwise thereto over 40 minutes. After completion of the dropwise addition, stirring was continued at 50° C. for 24 hours. Thereafter, 500 g of methyl isobutyl ketone and 100 g of pure water were added thereto. After the insoluble matter was separated by filtration, the aqueous layer was removed, and then the organic layer was washed 4 times with 100 g of pure water. The organic layer was dried to solidify under reduced pressure, then the residue was dissolved in 150 g of toluene, and the solution was charged into methanol and reprecipitated. The precipitate was collected by filtration, washed twice with 200 g of methanol, and then dried at 50° C. under vacuum, affording compound (A-16).

### [Synthesis Example 1-16] (Synthesis of Compound (a-17))

In a nitrogen atmosphere, 20.0 g of 2-acetylfluorene and 20.0 g of m-xylene were charged into a reaction vessel, and dissolved at 110° C. Then, 3.14 g of dodecylbenzenesulfonic acid was added, and the mixture was heated to 140° C. and reacted for 16 hours. After completion of the reaction, 80 g of xylene was added to the reaction solution to dilute the solution, and then the solution was cooled to 50° C. and charged into 500 g of methanol and reprecipitated. The resulting precipitate was washed with toluene, then the solid was collected with filter paper and dried, affording a compound represented by formula (a-17) (hereinafter, also referred to as “compound (a-17)”).

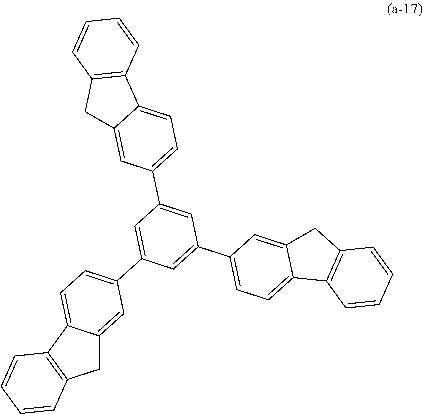 [SMILES: c1ccc2c(c1)Cc1cc(-c3cc(-c4ccc5c(c4)Cc4ccccc4-5)cc(-c4ccc5c(c4)Cc4ccccc4-5)c3)ccc1-2]

### [Synthesis Example 1-17] (Synthesis of Compound (A-17))

In a nitrogen atmosphere, 10.0 g of the compound (a-17), 7.2 g of p-ethynylbenzaldehyde, and 40 g of toluene were added to a reaction vessel, and the mixture was stirred. Then, 25.2 g of a 50% by mass aqueous sodium hydroxide solution and 1.7 g of tetrabutylammonium bromide were added thereto, and the mixture was reacted at room temperature for 6 hours. After the reaction, 25 g of tetrahydrofuran was added. After the aqueous phase was removed, 50 g of a 1% by mass aqueous oxalic acid solution was added, and the mixture was subjected to liquid-liquid separation-extraction. Then, the mixture was charged into hexane and reprecipitated. The precipitate was collected by filtration, affording compound (A-17).

### [Synthesis Example 1-18] (Synthesis of Polymer (A-18))

N-methyl-2-pyrrolidone (120 g) was added to 15.55 g of 4,4-(hexafluoroisopropylidene)diphthalic anhydride and 14.62 g of 1,3-bis(3-aminophenoxy)benzene, and the mixture was reacted at 40° C. for 3 hours in a nitrogen atmosphere. To the obtained compound was added 5.16 g of 4-ethynylphthalic anhydride, and the mixture was further reacted at 40° C. for 3 hours. To the obtained reaction solution was added 4.00 g of pyridine, 12.25 g of acetic anhydride was further added dropwise, and then the mixture was reacted at 60° C. for 4 hours. After completion of the reaction, the reaction mixture was cooled to room temperature, and 400 g of methyl isobutyl ketone was added. The organic layer was washed twice with 100 g of a 3% aqueous nitric acid solution, and further washed 6 times with 100 g of pure water, and the organic layer was dried to solidify under reduced pressure. Tetrahydrofuran (THF) (100 g) was added, and the mixture was charged into methanol and reprecipitated. The precipitate was collected by filtration, washed twice with 300 g of methanol, and then dried at 70° C. under vacuum, affording polymer (A-18). The Mw of the polymer (A-18) was 4,320.

### [Synthesis Example 1-19] (Synthesis of Polymer (A-19))

In a nitrogen atmosphere, 200 g of 1,2-dichloroethane and 13.1 g of methanesulfonic acid were slowly added to 30.0 g of 9-propargyl-9-fluorenol, and the mixture was reacted at 70° C. for 8 hours. After cooling to room temperature, 500 g of toluene was added, washing was performed 6 times with 100 g of pure water, and the organic layer was dried to solidify under reduced pressure. THF (100 g) was added, and the mixture was charged into methanol and reprecipitated. The precipitate was collected by filtration, washed twice with 200 g of methanol, and then dried at 70° C. under vacuum, affording polymer (A-19). The Mw of the polymer (A-19) was 2,450.

### [Synthesis Example 1-20] (Synthesis of Compound (A-20)

N-Methyl-2-pyrrolidone (120 g) was added to 7.91 g of 1,5-diaminonaphthalene and 17.21 g of 4-ethynylphthalic anhydride, and the mixture was reacted at 40° C. for 3 hours in a nitrogen atmosphere. Thereto was added 3.96 g of pyridine, 12.26 g of acetic anhydride was further slowly added dropwise, and then the mixture was reacted at 60° C. for 4 hours. After completion of the reaction, the reaction mixture was cooled to room temperature, and 300 g of methyl isobutyl ketone was added. The organic layer was washed with 100 g of a 3% nitric acid aqueous solution, and further washed 5 times with 100 g of pure water, and then the organic layer was dried to solidify under reduced pressure. THF (100 g) was added, and the mixture was charged into methanol and reprecipitated. The precipitate was collected by filtration, washed twice with 200 g of methanol, and then dried at 70° C. under vacuum, affording compound (A-20).

### [Synthesis Example 1-21] (Synthesis of Compound (A-21))

N-methyl-2-pyrrolidone (100 g) was added to 32.13 g of 9,9-bis[4-(3,4-dicarboxyphenoxy)phenyl]fluorene dianhydride, and 9.31 g of aniline dissolved in advance in 30 g of N-methyl-2-pyrrolidone was slowly added dropwise thereto under a nitrogen atmosphere, and the mixture was reacted at 40° C. for 3 hours. Thereto was added 130 g of o-xylene, and the mixture was reacted for 9 hours while water generated at 180° C. was removed from the system. After completion of the reaction, the reaction mixture was cooled to room temperature, charged into methanol, and reprecipitated. The precipitate was collected by filtration, washed twice with 300 g of methanol, and then dried at 70° C. under vacuum, affording compound (A-21).

### [Synthesis Example 1-22] (Synthesis of Compound (A-22))

The compound represented by formula (X-1) (1.8 g), 82.0 g of the compound represented by formula (x-2), 5 mL of β-mercaptopropionic acid, and 200 mL of 1,2-dichloroethane were made into a homogeneous solution at a liquid temperature of 60° C. under a nitrogen atmosphere. Subsequently, 10 mL of methanesulfonic acid was slowly added, and then the mixture was stirred at a liquid temperature of 70° C. for 12 hours. After cooling to room temperature, 400 g of methyl isobutyl ketone was added, and the organic layer was washed 5 times with 1,000 g of pure water, then the organic layer was dried to solidify under reduced pressure. To the residue was added 200 g of tetrahydrofuran (THF) to form a homogeneous solution, which was then crystallized in 1,000 g of hexane. The crystallized crystals were collected by filtration with a Kiriyama funnel, washed twice with 300 mL of hexane, and then the crystals were collected and dried at 60° C. under vacuum, affording compound (A-22).

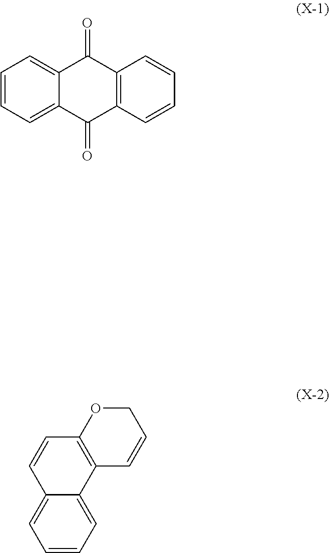 [SMILES: O=C1c2ccccc2C(=O)c2ccccc21 ; C1=Cc2c(ccc3ccccc23)OC1]

### [Synthesis Example 1-23] (Synthesis of Compound (A-23))

Under a nitrogen atmosphere, 15.0 g of trichlorotriazine, 28.6 g of 3-ethynylaniline, and 130.8 g of toluene were added to a reaction vessel, and the mixture was reacted at 0° C. for 1 hour. Thereafter, the mixture was reacted at 110° C. for 3 hours, affording compound (A-23).

### [Synthesis Example 1-24] (Synthesis of Polymer (A-24))

Under a nitrogen atmosphere, 10.0 g of 4,4′-(ax-methylbenzylidene)bisphenol and 6.28 g of 4-biphenylaldehyde were charged into a reaction vessel. Next, 47 g of 1-butanol was added thereto for dissolution, 3.28 g of p-toluenesulfonic acid monohydrate was then added, and the resultant was stirred at 110° C. for 6 hours for polymerization. After completion of the polymerization, the polymerization reaction solution was charged into a large amount of hexane, and the obtained precipitate was collected by filtration, affording polymer (A-24). The Mw of the polymer (A-24) was 4,600.

### [Synthesis Example 1-25] (Synthesis of Compound (A-25))

Under a nitrogen atmosphere, 10.0 g of the compound (a-17), 9.9 g of 1-naphthaldehyde, and 50 g of toluene were added to a reaction vessel, and stirred. Then, 25.2 g of a 50% by mass aqueous sodium hydroxide solution and 1.7 g of tetrabutylammonium bromide were added thereto, and the mixture was reacted at 92° C. for 12 hours. The reaction solution was cooled to 50° C., and then 25 g of tetrahydrofuran was added thereto. After removing the aqueous phase, 50 g of a 1% by mass aqueous oxalic acid solution was added, and the mixture was subjected to liquid-liquid separation-extraction. Then, the organic phase was charged into a large amount of hexane, and the obtained precipitate was collected by filtration, affording compound (A-25).

### [Synthesis Example 1-26] (Synthesis of Polymer (a-26))

Under a nitrogen atmosphere, 10.0 g of fluorene, 10.8 g of 9-fluorenone, and 62.5 g of chlorobenzene were added to a reaction vessel, and stirred. Then, 5.9 g of methanesulfonic acid was slowly added, and the mixture was reacted at 120° C. for 8 hours. The reaction solution was cooled to 50° C., washed 5 times with 100 g of pure water, then charged into a large amount of hexane. Then, the obtained precipitate was collected by filtration, affording polymer (a-26) which is represented by formula (a-26). The Mw of the polymer (a-26) was 2,100.

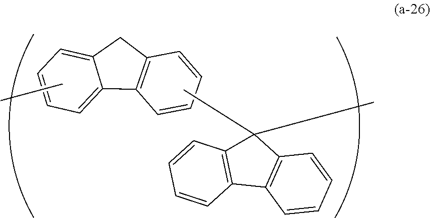

### [Synthesis Example 1-27] (Synthesis of Compound (A-26))

Under a nitrogen atmosphere, 10.0 g of the compound (a-26), 7.1 g of 2-naphthaldehyde, and 50 g of toluene were added to a reaction vessel, and stirred. Then, 7.3 g of a 50% by mass aqueous sodium hydroxide solution and 2.9 g of tetrabutylammonium bromide were added thereto, and the mixture was reacted at 92° C. for 12 hours. The reaction solution was cooled to 50° C., and then 25 g of tetrahydrofuran was added thereto. After removing the aqueous phase, 50 g of a 1% by mass aqueous oxalic acid solution was added, and the mixture was subjected to liquid-liquid separation-extraction. Then, the organic phase was charged into a large amount of hexane, and the obtained precipitate was collected by filtration, affording polymer (A-26). The Mw of the polymer (A-26) was 3,100.

### [Synthesis Example 1-28] (Synthesis of Polymer (A-27))

Polymer (A-27) was obtained in the same manner as in Synthesis Example 1-27 except that 7.1 g of 2-naphthaldehyde was changed to 5.9 g of 3-ethynylbenzaldehyde. The Mw of the polymer (A-27) was 3,000.

### [Synthesis Example 1-29] (Synthesis of Polymer (A-28))

Polymer (A-28) was obtained in the same manner as in Synthesis Example 1-27 except that 7.1 g of 2-naphthaldehyde was changed to 5.1 g of 2-thiophenecarboxyaldehyde. The Mw of the polymer (A-28) was 2,800.

### [Synthesis Example 1-30] (Synthesis of Polymer (a-29))

Under a nitrogen atmosphere, 10.0 g of fluorene, 14.1 g of 2-naphthaldehyde, and 48.2 g of chlorobenzene were added to a reaction vessel, and stirred. Then, 17.3 g of methanesulfonic acid was slowly added thereto, and the mixture was reacted at 120° C. for 8 hours. The reaction solution was cooled to 50° C., washed 5 times with 100 g of pure water, then charged into a large amount of hexane. Then, the obtained precipitate was collected by filtration, affording polymer (a-29) which is represented by formula (a-29). The Mw of the polymer (a-29) was 1,800.

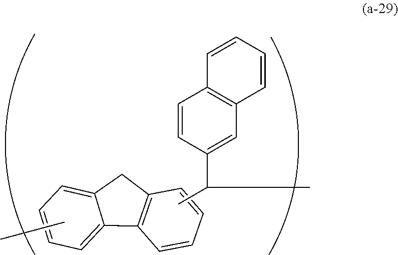

### [Synthesis Example 1-31] (Synthesis of Polymer (A-29))

Under a nitrogen atmosphere, 10.0 g of the polymer (a-29), 7.7 g of 2-naphthaldehyde, and 50 g of toluene were added to a reaction vessel, and stirred. Then, 7.9 g of a 50% by mass aqueous sodium hydroxide solution and 3.2 g of tetrabutylammonium bromide were added thereto, and the mixture was reacted at 92° C. for 12 hours. The reaction solution was cooled to 50° C., and then 25 g of tetrahydrofuran was added thereto. After removing the aqueous phase, 50 g of a 1% by mass aqueous oxalic acid solution was added, and the mixture was subjected to liquid-liquid separation-extraction. Then, the organic phase was charged into a large amount of hexane, and the obtained precipitate was collected by filtration, affording polymer (A-29). The Mw of the polymer (A-29) was 2,500.

### [Synthesis Example 1-32] (Synthesis of Polymer (a-30))

Under a nitrogen atmosphere, 10.0 g of fluorene, 11.1 g of acenaphthaquinone, and 62.9 g of chlorobenzene were added to a reaction vessel, and stirred. Then, 5.8 g of methanesulfonic acid was slowly added, and the mixture was reacted at 120° C. for 8 hours. The reaction solution was cooled to 50° C., washed 5 times with 100 g of pure water, then charged into a large amount of hexane. Then, the obtained precipitate was collected by filtration, affording polymer (a-30) which is represented by formula (a-30). The Mw of the polymer (a-30) was 2,200.

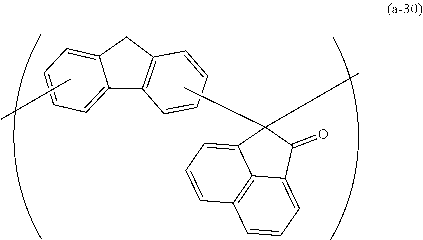

### [Synthesis Example 1-33] (Synthesis of Polymer (A-30))

Under a nitrogen atmosphere, 10.0 g of the compound (a-30), 7.1 g of 2-naphthaldehyde, and 50 g of toluene were added to a reaction vessel, and stirred. Then, 7.3 g of a 50% by mass aqueous sodium hydroxide solution and 2.9 g of tetrabutylammonium bromide were added thereto, and the mixture was reacted at 92° C. for 12 hours. The reaction solution was cooled to 50° C., and then 25 g of tetrahydrofuran was added thereto. After removing the aqueous phase, 50 g of a 1% by mass aqueous oxalic acid solution was added, and the mixture was subjected to liquid-liquid separation-extraction. Then, the organic phase was charged into a large amount of hexane, and the obtained precipitate was collected by filtration, affording polymer (A-30). The Mw of the polymer (A-30) was 3,000.

### [Synthesis Example 1-34] (Synthesis of Polymer (a-31))

Under a nitrogen atmosphere, 10.0 g of fluorene and 200.0 g of dichloromethane were added to a reaction vessel, then a mixed solution of 97.6 g of iron(III) chloride and 150.0 g of nitromethane was added dropwise thereto, and the mixture was reacted at room temperature for 50 hours. The precipitate was collected with filter paper, washed with 300.0 g of nitromethane and dried, affording polymer (a-31) represented by the following (a-31). The Mw of the polymer (a-31) was 1,400.

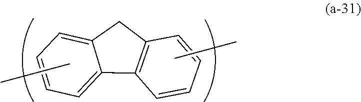

### [Synthesis Example 1-35] (Synthesis of Polymer (A-31))

Under a nitrogen atmosphere, 10.0 g of the polymer (a-31), 14.3 g of 2-naphthaldehyde, and 50 g of toluene were added to a reaction vessel, and stirred. Then, 14.6 g of a 50% by mass aqueous sodium hydroxide solution and 5.9 g of tetrabutylammonium bromide were added thereto, and the mixture was reacted at 92° C. for 12 hours. The reaction solution was cooled to 50° C., and then 25 g of tetrahydrofuran was added thereto. After removing the aqueous phase, 50 g of a 1% by mass aqueous oxalic acid solution was added, and the mixture was subjected to liquid-liquid separation-extraction. Then, the organic phase was charged into a large amount of hexane, and the obtained precipitate was collected by filtration, affording polymer (A-31). The Mw of the polymer (A-31) was 2,100.

### Synthesis of Polymer [B]

As the polymer [B], polymers represented by formulas (B-1) to (B-16) (hereinafter also referred to as “polymers (B-1) to (B-16)”) were synthesized by the following procedures.

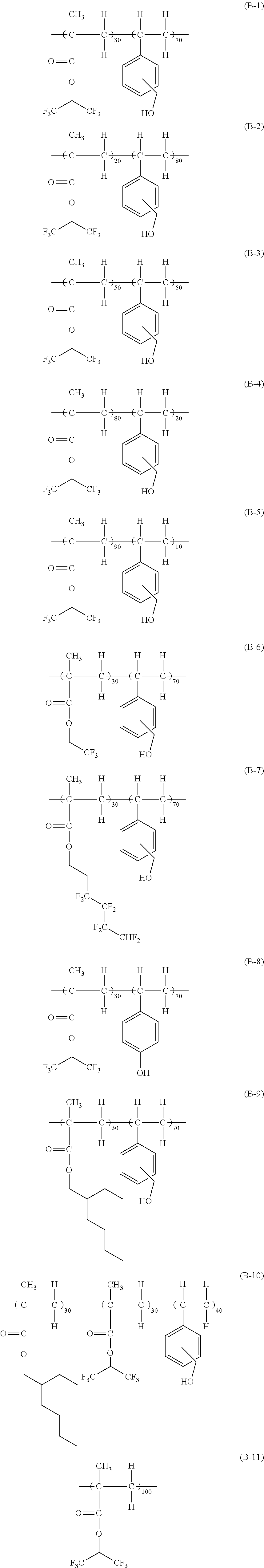

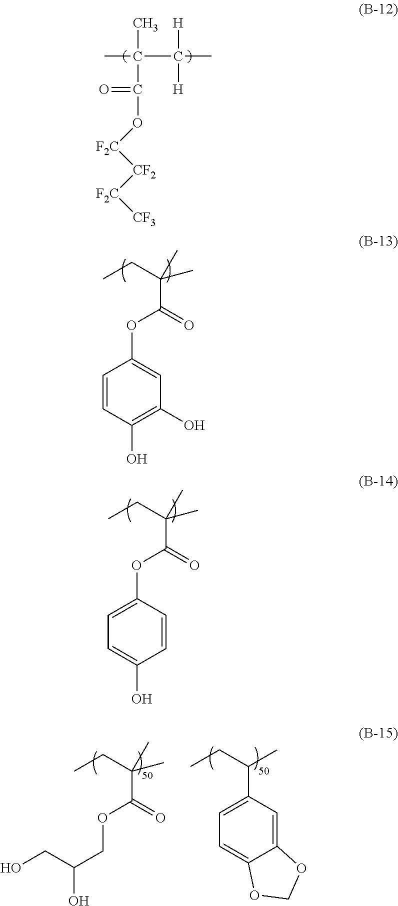

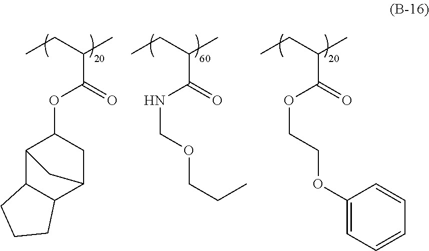

In the above formulas (B-1) to (B-16), the number attached to each structural unit indicates the content ratio (mol %) of the structural unit.

### [Synthesis Example 2-1] (Synthesis of Polymer (B-1))

1,1,1,3,3,3-Hexafluoroisopropyl methacrylate (43.0 g) and vinylbenzyl alcohol (57.0 g) were dissolved in 130 g of methyl isobutyl ketone, and 19.6 g of dimethyl 2,2′-azobis(2-methylpropionate) was added to prepare a monomer solution. In a nitrogen atmosphere, 70 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether acetate, and methyl isobutyl ketone was removed by concentration under reduced pressure, affording a propylene glycol monomethyl ether acetate solution of polymer (B-1). The Mw of the polymer (B-1) was 4,200.

### [Synthesis Examples 2-2 to 2-12] (Synthesis of Polymers (B-2) to (B-12))

Propylene glycol monomethyl ether acetate solutions of the polymers (B-2) to (B-12) were obtained in the same manner as in Synthesis Example 2-1 except that monomers capable of affording the structural units in the content ratios (mol %) shown in the formulas (B-2) to (B-12) were used. The Mw of the polymer (B-2) was 3,800, the Mw of the polymer (B-3) was 4,000, the Mw of the polymer (B-4) was 4,300, the Mw of the polymer (B-5) was 4,500, the Mw of the polymer (B-6) was 4,100, the Mw of the polymer (B-7) was 4,100, the Mw of the polymer (B-8) was 4,200, the Mw of the polymer (B-9) was 4,200, the Mw of the polymer (B-10) was 4,300, the Mw of the polymer (B-11) was 4,100, and the Mw of the polymer (B-12) was 4,400.

### [Synthesis Example 2-13] (Synthesis of Polymer (B-13))

3,4-Dihydroxyphenyl methacrylate (100.0 g) was dissolved in 130 g of methyl isobutyl ketone, and 16.6 g of dimethyl 2,2′-azobis(2-methylpropionate) was added to prepare a monomer solution. Under a nitrogen atmosphere, 70 g of methyl isobutyl ketone was placed in a reaction vessel and heated to 78° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether acetate, and methyl ethyl ketone was removed by concentration under reduced pressure, affording a propylene glycol monomethyl ether acetate solution of polymer (B-13). The Mw of the polymer (B-13) was 4,200.

### [Synthesis Example 2-14] (Synthesis of Polymer (B-14))

A propylene glycol monomethyl ether acetate solution of polymer (B-14) was obtained in the same manner as in Synthesis Example 1-12 except that 4-hydroxyphenyl methacrylate was used instead of 3,4-dihydroxyphenyl methacrylate. The Mw of the polymer (B-14) was 3,900.

### [Synthesis Example 2-15] (Synthesis of Polymer (B-15))

A solution of 5.50 g of glycerin monomethacrylate, 5.09 g of 5-vinylbenzo[d][1,3]dioxole, 0.66 g of 2,2′-azobis(isobutyronitrile), and 35.99 g of propylene glycol monomethyl ether acetate was charged into a dropping funnel, and the mixture was added dropwise at 100° C. under a nitrogen atmosphere into a reaction flask to which 9.00 g of propylene glycol monomethyl ether acetate had been added. The resulting mixture was heated and stirred for 20 hours. To the obtained solution were added 11 g of a cation-exchange resin (product name: Dowex [registered trademark] 550A, Muromachi Technos Co., Ltd.) and 11 g of an anion-exchange resin (product name: Amberlite [registered trademark] 15JWET, ORGANO Corporation), and then ion-exchange treatment was performed at room temperature for 4 hours. The ion-exchange resins were separated, affording a propylene glycol monomethyl ether acetate solution of polymer (B-15). The Mw of the polymer (B-15) was 9,000.

### [Synthesis Example 2-16] (Synthesis of Polymer (B-16))

Under a nitrogen atmosphere, 23.3 g of propylene glycol monomethyl ether acetate was heated and stirred at 80° C. To this, a mixture of 28.5 g of N-(butoxymethyl)acrylamide, 12.0 g of (2-phenoxyethyl) acrylate, 12.9 g of tricyclodecanyl acrylate, and 46.7 g of propylene glycol monomethyl ether acetate and a mixture of 4.45 g of dimethyl 2,2-azobis(2-methylpropionate) and 46.7 g of PGMEA were added simultaneously and separately over 2 hours. The mixture was heated and stirred for additional 16 hours, then cooled to 60° C., and 200 g of heptane was added. Then, the mixture was cooled to room temperature, and left at rest for 2 hours. The upper layer was separated and removed, 100 g of PGMEA was added, and then heptane was distilled off under reduced pressure, affording a propylene glycol monomethyl ether acetate solution of polymer (B-16). The Mw of the polymer (B-16) was 8,000.

### <Preparation of Composition>

The solvent [C]s, the [D] acid generators, the [E]oxidizing agent, and the [F] oxidizing agent used for the preparation of compositions are shown below.

### [Solvent [C]]

C-1: Propylene glycol monomethyl ether acetate
C-2: 1,6-Diacetoxyhexane
C-3: γ-Butyrolactone
C-4: Diethylene glycol dibutyl ether

### [[D] Acid Generator]

D-1: Bis(4-t-butylphenyl)iodonium nonafluoro-n-butanesulfonate (compound represented by formula (D-1))

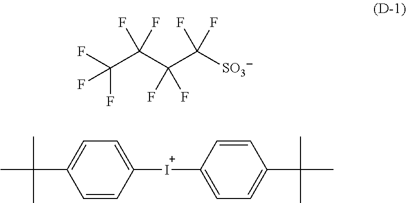

D-2: Compound represented by formula (D-2)

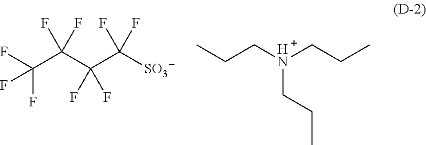

D-3: Compound represented by formula (D-3)

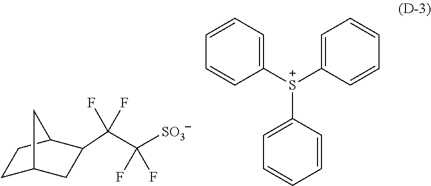

D-4: Compound represented by formula (D-4)

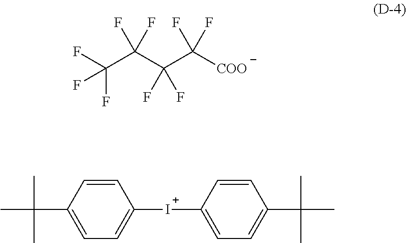

### ([E] Crosslinking Agent)

E-1: Compound represented by formula (E-1)

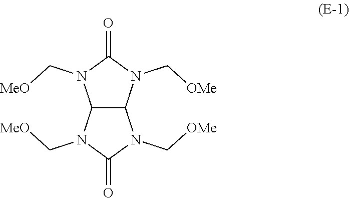 [SMILES: COCN1C(=O)N(COC)C2C1N(COC)C(=O)N2COC]

### [[F] Oxidizing Agent]

F-1: 2,3-Dichloro-5,6-dicyano-1,4-benzoquinone

### Example 1

100 parts by mass of (A-1) as the compound [A] and 3 parts by mass of (B-1) as the polymer [B] were dissolved in 1170 parts by mass of propylene glycol monomethyl ether acetate (C-1), and 130 parts by mass of 1,6-diacetoxyhexane (C-2) was added. The resulting solution was filtered through a polytetrafluoroethylene (PTFE) membrane filter having a pore size of 0.45 μm to prepare composition (J-1).

### Examples 2 to 61 and Comparative Examples 1 to 34

Compositions (J-2) to (J-61) and (CJ-1) to (CJ-31) were prepared in the same manner as in Example 1 except that the components of the types and contents shown in Tables 1 and 2 were used. In Comparative Examples 32 to 34, the compositions (J-1), (J-14), and (J-16) were used. “-” in the columns of “Polymer [B]”, “Acid generator [D]”, “Crosslinking agent [E]”, and “Oxidizing agent [F]” in Tables 1 and 2 indicates that the corresponding component was not used.

### <Evaluation>

Flatness and heat resistance were evaluated by the following procedures using the composition prepared as described above. The results are shown in Table 1 and Table 2.

### [Flatness]

The composition prepared as described above was applied to a silicon substrate 1 with a trench pattern formed thereon having a depth of 150 nm and a width of 10 μm as illustrated in the FIGURE by spin coating using a spin coater (“CLEAN TRACK ACT12” available from Tokyo Electron Ltd.). Next, the resultant was heated at 250° C. for 60 seconds in the air atmosphere, and then cooled at 23° C. for 60 seconds to form a resist underlayer coating film 2 having an average thickness of 300 nm in a non-trench pattern portion, and thus a silicon substrate with a resist underlayer coating film was obtained. The cross-sectional shape of the silicon substrate with a resist underlayer coating film was observed with a scanning electron microscope (“S-4800” manufactured by Hitachi High-Technologies Corporation). The difference (AFT) between the height of the resist underlayer coating film 2 at the central portion b of the trench pattern and the height of the non-trench pattern portion a which was 5 μm away from the end of the trench pattern was defined as an index of flatness. The flatness was evaluated as “A” (extremely good) when the AFT was less than 30 nm, “B” (good) when the AFT was 30 nm or more and less than 40 nm, and “C” (poor) when the AFT was 40 nm or more. The difference in height is shown in the FIGURE with exaggeration than actual one. In consideration of that the flatness of the coating was evaluated and that the flatness of the coating film was almost maintained even after the heating step, the flatness of the film before the heating step was evaluated.

### [Heat Resistance]

The film thickness before heating (firing) of the substrate with a resist underlayer film coating obtained as described above was measured using a spectroscopic ellipsometer (“M2000D” manufactured by J. A. WOOLLAM). Next, a resist underlayer film was formed by performing heating (firing) under a basic condition a basic condition, namely, at 500° C. for 300 seconds under a nitrogen atmosphere. The film thickness (film thickness after heating) of the resist underlayer film was measured, and the film thickness reduction ratio of the film thickness after heating to the film thickness before heating was calculated. The heat resistance was evaluated as “A” (extremely good) when the film thickness reduction rate was less than 10%, “B” (good) when the film thickness reduction rate was 10% or more and less than 20%, and “C” (poor) when the film thickness reduction rate was 20% or more. For Examples 1 to 61 and Comparative Examples 1 to 34, the oxygen concentration and the heating temperature at the time of heating the resist underlayer coating films were set as shown in Tables 1 and 2.

TABLE 1

| | | | | | | | | [D] | | [E] | | [F] | |
|---|---|---|---|---|---|---|---|---|---|---|---|---|---|
| | | Compound | | Polymer | | Solvent | | Acid | | Crosslinking | | Oxidizing | |
| | | [A] | | [B] | | [C] | | generator | | agent | | agent | |
| | | | Content | | Content | | Content | | Content | | Content | | Content |
| | | | (parts | | (parts | | (parts | | (parts | | (parts | | (parts |
| | Compo- | | by | | by | | by | | by | | by | | by |
| | sition | Type | mass) | Type | mass) | Type | mass) | Type | mass) | Type | mass) | Type | mass) |
| Example 1 | J-1 | A-1 | 100 | B-1 | 3 | C-1/C-2 | 1,170/130 | — | — | — | — | — | — |
| Example 2 | J-2 | A-2 | 100 | B-1 | 3 | C-1/C-2 | 1,170/130 | — | — | — | — | — | — |
| Example 3 | J-3 | A-3 | 100 | B-1 | 3 | C-1/C-2 | 1,170/130 | — | — | — | — | — | — |
| Example 4 | J-4 | A-4 | 100 | B-1 | 3 | C-1/C-2 | 1,170/130 | — | — | — | — | — | — |
| Example 5 | J-5 | A-5 | 100 | B-1 | 3 | C-1/C-2 | 1,170/130 | — | — | — | — | — | — |
| Example 6 | J-6 | A-6 | 100 | B-1 | 3 | C-1/C-2 | 1,170/130 | — | — | — | — | — | — |
| Example 7 | J-7 | A-7 | 100 | B-1 | 3 | C-1/C-2 | 1,170/130 | — | — | — | — | — | — |
| Example 8 | J-8 | A-8 | 100 | B-1 | 3 | C-1/C-2 | 1,170/130 | — | — | — | — | — | — |
| Example 9 | J-9 | A-9 | 100 | B-1 | 3 | C-1/C-2 | 1,170/130 | — | — | — | — | — | — |
| Example 10 | J-10 | A-10 | 100 | B-1 | 3 | C-1/C-2 | 1,170/130 | — | — | — | — | — | — |
| Example 11 | J-11 | A-11 | 100 | B-1 | 3 | C-1/C-2 | 1,170/130 | — | — | — | — | — | — |
| Example 12 | J-12 | A-12 | 100 | B-1 | 3 | C-1/C-2 | 1,170/130 | — | — | — | — | — | — |
| Example 13 | J-13 | A-13 | 100 | B-1 | 3 | C-1/C-2 | 1,170/130 | — | — | — | — | — | — |
| Example 14 | J-14 | A-14 | 100 | B-1 | 3 | C-1/C-2 | 1,170/130 | — | — | — | — | — | — |
| Example 15 | J-15 | A-15 | 100 | B-1 | 3 | C-1/C-2 | 1,170/130 | — | — | — | — | — | — |
| Example 16 | J-16 | A-16 | 100 | B-1 | 3 | C-1/C-2 | 1,170/130 | — | — | — | — | — | — |
| Example 17 | J-17 | A-17 | 100 | B-1 | 3 | C-1/C-2 | 1,170/130 | — | — | — | — | — | — |
| Example 18 | J-18 | A-18 | 100 | B-1 | 3 | C-1/C-2 | 1,170/130 | — | — | — | — | — | — |
| Example 19 | J-19 | A-19 | 100 | B-1 | 3 | C-1/C-2 | 1,170/130 | — | — | — | — | — | — |
| Example 20 | J-20 | A-20 | 100 | B-1 | 3 | C-1/C-2 | 1,170/130 | — | — | — | — | — | — |
| Example 21 | J-21 | A-21 | 100 | B-1 | 3 | C-1/C-2 | 1,170/130 | — | — | — | — | — | — |
| Example 22 | J-22 | A-22 | 100 | B-1 | 3 | C-1/C-2 | 1,170/130 | — | — | — | — | — | — |
| Example 23 | J-23 | A-23 | 100 | B-1 | 3 | C-1/C-2 | 1,170/130 | — | — | — | — | — | — |
| Example 24 | J-24 | A-24 | 100 | B-1 | 3 | C-1/C-2 | 1,170/130 | — | — | — | — | — | — |
| Example 25 | J-25 | A-25 | 100 | B-1 | 3 | C-1/C-2 | 1,170/130 | D-1 | 1 | — | — | F-1 | 1 |
| Example 26 | J-26 | A-26 | 100 | B-1 | 3 | C-1/C-2 | 1,170/130 | D-1 | 1 | — | — | F-1 | 1 |
| Example 27 | J-27 | A-27 | 100 | B-1 | 3 | C-1/C-2 | 1,170/130 | D-1 | 1 | — | — | F-1 | 1 |
| Example 28 | J-28 | A-28 | 100 | B-1 | 3 | C-1/C-2 | 1,170/130 | D-1 | 1 | — | — | F-1 | 1 |
| Example 29 | J-29 | A-29 | 100 | B-1 | 3 | C-1/C-2 | 1,170/130 | D-1 | 1 | — | — | F-1 | 1 |
| Example 30 | J-30 | A-30 | 100 | B-1 | 3 | C-1/C-2 | 1,170/130 | D-1 | 1 | — | — | F-1 | 1 |

| | Oxygen concentration during | Heating temperature during | | |
|---|---|---|---|---|
| | heating of resist underlayer | heating of resist underlayer | | |
| | coating film | coating film | | |
| | (% by volume) | (° C.) | Flatness | Heat resistance |
| Example 1 | 0.002 | 500 | A | B |
| Example 2 | 0.002 | 500 | A | B |
| Example 3 | 0.002 | 500 | A | A |
| Example 4 | 0.002 | 500 | A | A |
| Example 5 | 0.002 | 500 | A | A |
| Example 6 | 0.002 | 500 | A | A |
| Example 7 | 0.002 | 500 | A | A |
| Example 8 | 0.002 | 500 | A | A |
| Example 9 | 0.002 | 500 | A | B |
| Example 10 | 0.002 | 500 | A | B |
| Example 11 | 0.002 | 500 | A | A |
| Example 12 | 0.002 | 500 | A | A |
| Example 13 | 0.002 | 500 | A | A |
| Example 14 | 0.002 | 500 | A | A |
| Example 15 | 0.002 | 500 | A | A |
| Example 16 | 0.002 | 500 | A | A |
| Example 17 | 0.002 | 500 | A | A |
| Example 18 | 0.002 | 500 | A | A |
| Example 19 | 0.002 | 500 | A | A |
| Example 20 | 0.002 | 500 | A | A |
| Example 21 | 0.002 | 500 | A | A |
| Example 22 | 0.002 | 500 | A | A |
| Example 23 | 0.002 | 500 | A | A |
| Example 24 | 0.002 | 500 | A | A |
| Example 25 | 0.002 | 500 | A | A |
| Example 26 | 0.002 | 500 | A | A |
| Example 27 | 0.002 | 500 | A | A |
| Example 28 | 0.002 | 500 | A | A |
| Example 29 | 0.002 | 500 | A | A |
| Example 30 | 0.002 | 500 | A | A |

| | | | | | | | | [D] | | [E] | | [F] | |
|---|---|---|---|---|---|---|---|---|---|---|---|---|---|
| | | Compound | | Polymer | | Solvent | | Acid | | Crosslinking | | Oxidizing | |
| | | [A] | | [B] | | [C] | | generator | | agent | | agent | |
| | | | Content | | Content | | Content | | Content | | Content | | Content |
| | | | (parts | | (parts | | (parts | | (parts | | (parts | | (parts |
| | Compo- | | by | | by | | by | | by | | by | | by |
| | sition | Type | mass) | Type | mass) | Type | mass) | Type | mass) | Type | mass) | Type | mass) |
| Example 31 | J-31 | A-31 | 100 | B-1 | 3 | C-1/C-2 | 1,170/130 | D-1 | 1 | — | — | F-1 | 1 |
| Example 32 | J-32 | A-14 | 100 | B-2 | 3 | C-1/C-2 | 1,170/130 | — | — | — | — | — | — |
| Example 33 | J-33 | A-14 | 100 | B-3 | 3 | C-1/C-2 | 1,170/130 | — | — | — | — | — | — |
| Example 34 | J-34 | A-14 | 100 | B-4 | 3 | C-1/C-2 | 1,170/130 | — | — | — | — | — | — |
| Example 35 | J-35 | A-14 | 100 | B-5 | 3 | C-1/C-2 | 1,170/130 | — | — | — | — | — | — |
| Example 36 | J-36 | A-14 | 100 | B-6 | 3 | C-1/C-2 | 1,170/130 | — | — | — | — | — | — |
| Example 37 | J-37 | A-14 | 100 | B-7 | 3 | C-1/C-2 | 1,170/130 | — | — | — | — | — | — |
| Example 38 | J-38 | A-14 | 100 | B-8 | 3 | C-1/C-2 | 1,170/130 | — | — | — | — | — | — |
| Example 39 | J-39 | A-14 | 100 | B-9 | 3 | C-1/C-2 | 1,170/130 | — | — | — | — | — | — |
| Example 40 | J-40 | A-14 | 100 | B-10 | 3 | C-1/C-2 | 1,170/130 | — | — | — | — | — | — |
| Example 41 | J-41 | A-14 | 100 | B-11 | 3 | C-1/C-2 | 1,170/130 | — | — | — | — | — | — |
| Example 42 | J-42 | A-14 | 100 | B-12 | 3 | C-1/C-2 | 1,170/130 | — | — | — | — | — | — |
| Example 43 | J-43 | A-14 | 100 | B-13 | 3 | C-1/C-2 | 1,170/130 | — | — | — | — | — | — |
| Example 44 | J-44 | A-14 | 100 | B-1 | 1 | C-1/C-2 | 1,170/130 | — | — | — | — | — | — |
| Example 45 | J-45 | A-14 | 100 | B-1 | 5 | C-1/C-2 | 1,170/130 | — | — | — | — | — | — |
| Example 46 | J-46 | A-14 | 100 | B-1 | 10 | C-1/C-2 | 1,170/130 | — | — | — | — | — | — |
| Example 47 | J-47 | A-14 | 100 | B-1 | 20 | C-1/C-2 | 1,170/130 | — | — | — | — | — | — |
| Example 48 | J-48 | A-14 | 100 | B-1 | 3 | C-1/C-2 | 1,170/130 | — | — | — | — | — | — |
| Example 49 | J-49 | A-14 | 100 | B-1 | 3 | C-1/C-3 | 1,170/130 | — | — | — | — | — | — |
| Example 50 | J-50 | A-14 | 100 | B-1 | 3 | C-1/C-4 | 1,170/130 | — | — | — | — | — | — |
| Example 51 | J-51 | A-14 | 100 | B-1/ | 3/5 | C-1/C-2 | 1,170/130 | — | — | — | — | — | — |
| | | | | B-14 | | | | | | | | | |
| Example 52 | J-52 | A-14 | 100 | B-1/ | 3/5 | C-1/C-2 | 1,170/130 | — | — | — | — | — | — |
| | | | | B-15 | | | | | | | | | |
| Example 53 | J-53 | A-14 | 100 | B-1/ | 3/5 | C-1/C-2 | 1,170/130 | — | — | — | — | — | — |
| | | | | B-16 | | | | | | | | | |
| Example 54 | J-54 | A-14 | 100 | B-1 | 3 | C-1/C-2 | 1,170/130 | — | — | — | — | — | — |
| Example 55 | J-55 | A-14 | 100 | B-1 | 3 | C-1/C-2 | 1,170/130 | — | — | — | — | — | — |
| Example 56 | J-56 | A-16 | 100 | B-1 | 3 | C-1/C-2 | 1,170/130 | — | — | — | — | — | — |
| Example 57 | J-57 | A-16 | 100 | B-1 | 3 | C-1/C-2 | 1,170/130 | — | — | — | — | — | — |
| Example 58 | J-58 | A-1 | 100 | B-1 | 3 | C-1/C-2 | 1,170/130 | D-1 | 4 | E-1 | 10 | — | — |
| Example 59 | J-59 | A-25 | 100 | B-1 | 3 | C-1/C-2 | 1,170/130 | D-2 | 1 | — | — | F-1 | 1 |
| Example 60 | J-60 | A-25 | 100 | B-1 | 3 | C-1/C-2 | 1,170/130 | D-3 | 1 | — | — | F-1 | 1 |
| Example 61 | J-61 | A-25 | 100 | B-1 | 3 | C-1/C-2 | 1,170/130 | D-4 | 1 | — | — | F-1 | 1 |

| | Oxygen concentration during | Heating temperature during | | |
|---|---|---|---|---|
| | heating of resist underlayer | heating of resist underlayer | | |
| | coating film | coating film | | |
| | (% by volume) | (° C.) | Flatness | Heat resistance |
| Example 31 | 0.002 | 500 | A | A |
| Example 32 | 0.002 | 500 | A | A |
| Example 33 | 0.002 | 500 | A | A |
| Example 34 | 0.002 | 500 | A | A |
| Example 35 | 0.002 | 500 | A | A |
| Example 36 | 0.002 | 500 | A | A |
| Example 37 | 0.002 | 500 | A | A |
| Example 38 | 0.002 | 500 | B | A |
| Example 39 | 0.002 | 500 | B | A |
| Example 40 | 0.002 | 500 | A | A |
| Example 41 | 0.002 | 500 | B | A |
| Example 42 | 0.002 | 500 | B | A |
| Example 43 | 0.002 | 500 | B | A |
| Example 44 | 0.002 | 500 | A | A |
| Example 45 | 0.002 | 500 | A | A |
| Example 46 | 0.002 | 500 | A | A |
| Example 47 | 0.002 | 500 | A | A |
| Example 48 | 0.002 | 500 | A | A |
| Example 49 | 0.002 | 500 | A | A |
| Example 50 | 0.002 | 500 | A | A |
| Example 51 | 0.002 | 500 | A | A |
| Example 52 | 0.002 | 500 | A | A |
| Example 53 | 0.002 | 500 | A | A |
| Example 54 | 0.002 | 450 | A | A |
| Example 55 | 0.002 | 550 | A | A |
| Example 56 | 0.002 | 450 | A | A |
| Example 57 | 0.002 | 550 | A | A |
| Example 58 | 0.002 | 500 | A | B |
| Example 59 | 0.002 | 500 | A | A |
| Example 60 | 0.002 | 500 | A | A |
| Example 61 | 0.002 | 500 | A | A |

TABLE 2

| | | | | | | | | [D] | | [E] | | [F] | |
|---|---|---|---|---|---|---|---|---|---|---|---|---|---|
| | | Compound | | Polymer | | Solvent | | Acid | | Crosslinking | | Oxidizing | |
| | | [A] | | [B] | | [C] | | generator | | agent | | agent | |
| | | | Content | | Content | | Content | | Content | | Content | | Content |
| | | | (parts | | (parts | | (parts | | (parts | | (parts | | (parts |
| | Compo- | | by | | by | | by | | by | | by | | by |
| | sition | Type | mass) | Type | mass) | Type | mass) | Type | mass) | Type | mass) | Type | mass) |
| Comparative | CJ-1 | A-1 | 100 | — | — | C-1/C-2 | 1,170/130 | — | — | — | — | — | — |
| Example 1 | | | | | | | | | | | | | |
| Comparative | CJ-2 | A-2 | 100 | — | — | C-1/C-2 | 1,170/130 | — | — | — | — | — | — |
| Example 2 | | | | | | | | | | | | | |
| Comparative | CJ-3 | A-3 | 100 | — | — | C-1/C-2 | 1,170/130 | — | — | — | — | — | — |
| Example 3 | | | | | | | | | | | | | |
| Comparative | CJ-4 | A-4 | 100 | — | — | C-1/C-2 | 1,170/130 | — | — | — | — | — | — |
| Example 4 | | | | | | | | | | | | | |
| Comparative | CJ-5 | A-5 | 100 | — | — | C-1/C-2 | 1,170/130 | — | — | — | — | — | — |
| Example 5 | | | | | | | | | | | | | |
| Comparative | CJ-6 | A-6 | 100 | — | — | C-1/C-2 | 1,170/130 | — | — | — | — | — | — |
| Example 6 | | | | | | | | | | | | | |
| Comparative | CJ-7 | A-7 | 100 | — | — | C-1/C-2 | 1,170/130 | — | — | — | — | — | — |
| Example 7 | | | | | | | | | | | | | |
| Comparative | CJ-8 | A-8 | 100 | — | — | C-1/C-2 | 1,170/130 | — | — | — | — | — | — |
| Example 8 | | | | | | | | | | | | | |
| Comparative | CJ-9 | A-9 | 100 | — | — | C-1/C-2 | 1,170/130 | — | — | — | — | — | — |
| Example 9 | | | | | | | | | | | | | |
| Comparative | CJ-10 | A-10 | 100 | — | — | C-1/C-2 | 1,170/130 | — | — | — | — | — | — |
| Example 10 | | | | | | | | | | | | | |
| Comparative | CJ-11 | A-11 | 100 | — | — | C-1/C-2 | 1,170/130 | — | — | — | — | — | — |
| Example 11 | | | | | | | | | | | | | |
| Comparative | CJ-12 | A-12 | 100 | — | — | C-1/C-2 | 1,170/130 | — | — | — | — | — | — |
| Example 12 | | | | | | | | | | | | | |
| Comparative | CJ-13 | A-13 | 100 | — | — | C-1/C-2 | 1,170/130 | — | — | — | — | — | — |
| Example 13 | | | | | | | | | | | | | |
| Comparative | CJ-14 | A-14 | 100 | — | — | C-1/C-2 | 1,170/130 | — | — | — | — | — | — |
| Example 14 | | | | | | | | | | | | | |
| Comparative | CJ-15 | A-15 | 100 | — | — | C-1/C-2 | 1,170/130 | — | — | — | — | — | — |
| Example 15 | | | | | | | | | | | | | |
| Comparative | CJ-16 | A-16 | 100 | — | — | C-1/C-2 | 1,170/130 | — | — | — | — | — | — |
| Example 16 | | | | | | | | | | | | | |
| Comparative | CJ-17 | A-17 | 100 | — | — | C-1/C-2 | 1,170/130 | — | — | — | — | — | — |
| Example 17 | | | | | | | | | | | | | |

| | Oxygen concentration during | Heating temperature during | | |
|---|---|---|---|---|
| | heating of resist underlayer | heating of resist underlayer | | |
| | coating film | coating film | | |
| | (% by volume) | (°C.) | Flatness | Heat resistance |
| Comparative | 0.002 | 500 | C | B |
| Example 1 | | | | |
| Comparative | 0.002 | 500 | C | B |
| Example 2 | | | | |
| Comparative | 0.002 | 500 | C | A |
| Example 3 | | | | |
| Comparative | 0.002 | 500 | C | A |
| Example 4 | | | | |
| Comparative | 0.002 | 500 | C | A |
| Example 5 | | | | |
| Comparative | 0.002 | 500 | C | A |
| Example 6 | | | | |
| Comparative | 0.002 | 500 | C | A |
| Example 7 | | | | |
| Comparative | 0.002 | 500 | C | A |
| Example 8 | | | | |
| Comparative | 0.002 | 500 | C | B |
| Example 9 | | | | |
| Comparative | 0.002 | 500 | C | B |
| Example 10 | | | | |
| Comparative | 0.002 | 500 | C | A |
| Example 11 | | | | |
| Comparative | 0.002 | 500 | C | A |
| Example 12 | | | | |
| Comparative | 0.002 | 500 | C | A |
| Example 13 | | | | |
| Comparative | 0.002 | 500 | C | A |
| Example 14 | | | | |
| Comparative | 0.002 | 500 | C | A |
| Example 15 | | | | |
| Comparative | 0.002 | 500 | C | A |
| Example 16 | | | | |
| Comparative | 0.002 | 500 | C | A |
| Example 17 | | | | |

| | | | | | | | | [D] | | [E] | | [F] | |
|---|---|---|---|---|---|---|---|---|---|---|---|---|---|
| | | Compound | | Polymer | | Solvent | | Acid | | Crosslinking | | Oxidizing | |
| | | [A] | | [B] | | [C] | | generator | | agent | | agent | |
| | | | Content | | Content | | Content | | Content | | Content | | Content |
| | | | (parts | | (parts | | (parts | | (parts | | (parts | | (parts |
| | Compo- | | by | | by | | by | | by | | by | | by |
| | sition | Type | mass) | Type | mass) | Type | mass) | Type | mass) | Type | mass) | Type | mass) |
| Comparative | CJ-18 | A-18 | 100 | — | — | C-1/C-2 | 1,170/130 | — | — | — | — | — | — |
| Example 18 | | | | | | | | | | | | | |
| Comparative | CJ-19 | A-19 | 100 | — | — | C-1/C-2 | 1,170/130 | — | — | — | — | — | — |
| Example 19 | | | | | | | | | | | | | |
| Comparative | CJ-20 | A-20 | 100 | — | — | C-1/C-2 | 1,170/130 | — | — | — | — | — | — |
| Example 20 | | | | | | | | | | | | | |
| Comparative | CJ-21 | A-21 | 100 | — | — | C-1/C-2 | 1,170/130 | — | — | — | — | — | — |
| Example 21 | | | | | | | | | | | | | |
| Comparative | CJ-22 | A-22 | 100 | — | — | C-1/C-2 | 1,170/130 | — | — | — | — | — | — |
| Example 22 | | | | | | | | | | | | | |
| Comparative | CJ-23 | A-23 | 100 | — | — | C-1/C-2 | 1,170/130 | — | — | — | — | — | — |
| Example 23 | | | | | | | | | | | | | |
| Comparative | CJ-24 | A-24 | 100 | — | — | C-1/C-2 | 1,170/130 | — | — | — | — | — | — |
| Example 24 | | | | | | | | | | | | | |
| Comparative | CJ-25 | A-25 | 100 | — | — | C-1/C-2 | 1,170/130 | D-1 | 1 | — | — | F-1 | 1 |
| Example 25 | | | | | | | | | | | | | |
| Comparative | CJ-26 | A-26 | 100 | — | — | C-1/C-2 | 1,170/130 | D-1 | 1 | — | — | F-1 | 1 |
| Example 26 | | | | | | | | | | | | | |
| Comparative | CJ-27 | A-27 | 100 | — | — | C-1/C-2 | 1,170/130 | D-1 | 1 | — | — | F-1 | 1 |
| Example 27 | | | | | | | | | | | | | |
| Comparative | CJ-28 | A-28 | 100 | — | — | C-1/C-2 | 1,170/130 | D-1 | 1 | — | — | F-1 | 1 |
| Example 28 | | | | | | | | | | | | | |
| Comparative | CJ-29 | A-29 | 100 | — | — | C-1/C-2 | 1,170/130 | D-1 | 1 | — | — | F-1 | 1 |
| Example 29 | | | | | | | | | | | | | |
| Comparative | CJ-30 | A-30 | 100 | — | — | C-1/C-2 | 1,170/130 | D-1 | 1 | — | — | F-1 | 1 |
| Example 30 | | | | | | | | | | | | | |
| Comparative | CJ-31 | A-31 | 100 | — | — | C-1/C-2 | 1,170/130 | D-1 | 1 | — | — | F-1 | 1 |
| Example 31 | | | | | | | | | | | | | |
| Comparative | J-14 | A-14 | 100 | B-1 | 3 | C-1/C-2 | 1,170/130 | — | — | — | — | — | — |
| Example 32 | | | | | | | | | | | | | |
| Comparative | J-16 | A-16 | 100 | B-1 | 3 | C-1/C-2 | 1,170/130 | — | — | — | — | — | — |
| Example 33 | | | | | | | | | | | | | |
| Comparative | J-1 | A-1 | 100 | B-1 | 3 | C-1/C-2 | 1,170/130 | — | — | — | — | — | — |
| Example 34 | | | | | | | | | | | | | |

| | Oxygen concentration during | Heating temperature during | | |
|---|---|---|---|---|
| | heating of resist underlayer | heating of resist underlayer | | |
| | coating film | coating film | | |
| | (% by volume) | (°C.) | Flatness | Heat resistance |
| Comparative | 0.002 | 500 | C | A |
| Example 18 | | | | |
| Comparative | 0.002 | 500 | C | A |
| Example 19 | | | | |
| Comparative | 0.002 | 500 | C | A |
| Example 20 | | | | |
| Comparative | 0.002 | 500 | C | A |
| Example 21 | | | | |
| Comparative | 0.002 | 500 | C | A |
| Example 22 | | | | |
| Comparative | 0.002 | 500 | C | A |
| Example 23 | | | | |
| Comparative | 0.002 | 500 | C | A |
| Example 24 | | | | |
| Comparative | 0.002 | 500 | C | A |
| Example 25 | | | | |
| Comparative | 0.002 | 500 | C | A |
| Example 26 | | | | |
| Comparative | 0.002 | 500 | C | A |
| Example 27 | | | | |
| Comparative | 0.002 | 500 | C | A |
| Example 28 | | | | |
| Comparative | 0.002 | 500 | C | A |
| Example 29 | | | | |
| Comparative | 0.002 | 500 | C | A |
| Example 30 | | | | |
| Comparative | 0.002 | 500 | C | A |
| Example 31 | | | | |
| Comparative | 0.002 | 400 | A | C |
| Example 32 | | | | |
| Comparative | 0.002 | 400 | A | C |
| Example 33 | | | | |
| Comparative | 20 | 500 | A | C |
| Example 34 | | | | |

As can be seen from the results in Tables 1 and 2, the resist underlayer films formed in Examples were superior in flatness and heat resistance to the resist underlayer films formed in Comparative Examples.

The method for forming a resist underlayer film of the present disclosure makes it possible to form a resist underlayer film excellent in heat resistance and flatness can be formed. By use of the method for manufacturing a semiconductor substrate of the present disclosure, a resist underlayer film excellent in heat resistance and flatness is formed, and therefore, a favorable semiconductor substrate can be obtained. The composition for forming a resist underlayer film of the present disclosure can form a resist underlayer film excellent in heat resistance and flatness. The resist underlayer film formed of the composition for forming a resist underlayer film of the present disclosure is excellent in heat resistance and flatness. Therefore, these can be suitably used for the manufacture of a semiconductor substrate, etc.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for forming a resist underlayer film, comprising:
applying a composition for forming a resist underlayer film directly or indirectly to a substrate to form a coating film; and
heating the coating film at a heating temperature of higher than 450° C. and 600° C. or lower in an atmosphere having an oxygen concentration of less than 0.01% by volume,
wherein
the composition for forming a resist underlayer film comprises:
a compound comprising an aromatic ring;
a polymer which thermally decomposes at the heating temperature in heating the coating film, and which is other than the compound; and
a solvent,
the compound has a molecular weight of 400 or more, and
a content of the polymer is less than a content of the compound in the composition for forming a resist underlayer film.

2. The method according to claim 1, wherein the polymer comprises a first structural unit represented by formula (B1): 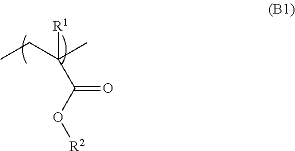
wherein, in the formula (B1), R¹ is a hydrogen atom, a halogen atom, or a monovalent organic group having 1 to 20 carbon atoms; and R² is a monovalent organic group having 1 to 20 carbon atoms.

3. The method according to claim 1, wherein a content of the polymer based on 100 parts by mass of the compound is 0.1 parts by mass or more and 50 parts by mass or less.

4. A method for manufacturing a semiconductor substrate, comprising:
applying a composition for forming a resist underlayer film directly or indirectly to a substrate to form a coating film;
heating the coating film at a heating temperature of higher than 450° C. and 600° C. or lower in an atmosphere having an oxygen concentration of less than 0.01% by volume to form a resist underlayer film;
forming a resist pattern directly or indirectly on the resist underlayer film; and
performing etching using the resist pattern as a mask,
wherein
the composition for forming a resist underlayer film comprises:
a compound comprising an aromatic ring;
a polymer which thermally decomposes at the heating temperature in heating the coating film, and which is other than the compound; and
a solvent,
the compound has a molecular weight of 400 or more, and
a content of the polymer is less than a content of the compound in the composition for forming a resist underlayer film.

5. The method according to claim 4, wherein the polymer comprises a first structural unit represented by formula (B1): 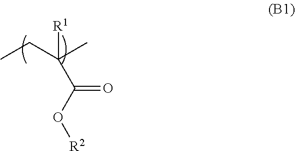
wherein, in the formula (B1), R¹ is a hydrogen atom, a halogen atom, or a monovalent organic group having 1 to 20 carbon atoms; and R² is a monovalent organic group having 1 to 20 carbon atoms.

6. The method according to claim 4, wherein a content of the polymer based on 100 parts by mass of the compound is 0.1 parts by mass or more and 50 parts by mass or less.

7. The method according to claim 4, further comprising:
forming a silicon-containing film directly or indirectly on the resist underlayer film before forming the resist pattern.

8. A composition comprises:
a compound comprising an aromatic ring;
a polymer which thermally decomposes at a heating temperature of higher than 450° C. and 600° C. or lower, and which is other than the compound; and
a solvent,
the compound has a molecular weight of 400 or more, and
a content of the polymer is less than a content of the compound in the composition.

9. The composition according to claim 8, wherein the polymer comprises a first structural unit represented by formula (B1): 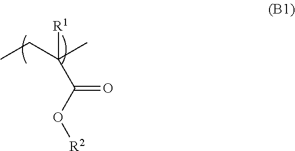
wherein, in the formula (B1), R¹ is a hydrogen atom, a halogen atom, or a monovalent organic group having 1 to 20 carbon atoms; and R² is a monovalent organic group having 1 to 20 carbon atoms.

10. The composition according to claim 8, wherein a content of the polymer based on 100 parts by mass of the compound is 0.1 parts by mass or more and 50 parts by mass or less.

11. A resist underlayer film formed of the composition according to claim 8.
